(19) United States
(12) Patent Application Publication
(10) Pub. No.: US 2013/0148436 A1
(43) Pub. Date: Jun. 13, 2013

(54) SEMICONDUCTOR MEMORY DEVICE WHICH STORES MULTIVALUED DATA

(71) Applicant: Yasuhiko KUROSAWA, Fujisawa-shi (JP)

(72) Inventor: Yasuhiko KUROSAWA, Fujisawa-shi (JP)

(21) Appl. No.: 13/544,147

(22) Filed: Jul. 9, 2012

(30) Foreign Application Priority Data
Dec. 12, 2011 (JP) 2011-271393

(51) Int. Cl. G11C 16/26

(52) U.S. Cl. 365/185.24

(57) ABSTRACT

According to one embodiment, a semiconductor memory device includes a memory and a controller. The memory includes a plurality of memory cells each of which stores data when one of an n number of threshold voltages (n being a natural number not less than two) is set. The controller reads data from the memory. The controller reads data from the memory cells at each of the threshold voltages in a read operation that checks a distribution of threshold voltages of the memory cells, calculates difference data on data read at each of the threshold voltages, calculates a minimum value of the distribution of the threshold voltages from the difference data, calculates a range of threshold voltages lower than the minimum value based on the minimum value, and sets a central voltage in the calculated range of threshold voltages as a read voltage.

### CROSS-REFERENCE TO RELATED APPLICATIONS

This application is based upon and claims the benefit of priority from prior Japanese Patent Application No. 2011-271393, filed Dec. 12, 2011, the entire contents of which are incorporated herein by reference.

### FIELD

Embodiments described herein relate generally to a semiconductor memory device, such as a NAND flash memory which stores multivalued data.

### BACKGROUND

When stress is applied to a NAND flash memory, particularly to a multivalued NAND flash memory capable of storing a plurality of bits of data in a cell, or when a long time has elapsed since data was written, the charge of each memory cell increases or decreases, resulting in a change in the threshold voltage. Therefore, the threshold voltage in reading data from a memory cell has deviated from a preset optimum value, disabling data stored in the memory cell from being read accurately. As a result, the bit error rate, the rate of the number of error bits included in read data, increases.

Errors that occur due to a fluctuation in the threshold voltage can be corrected to some extent by adding error correction code (ECC). However, when the bit error rate is high, this makes correction difficult even if ECC is used.

To decrease the bit error rate, it is necessary to optimize a read voltage of a memory cell. To do that, the distribution of the threshold voltages of memory cells has to be searched for accurately. Therefore, a semiconductor memory device capable of accurately searching for the distribution of the threshold voltages of memory cells has been desired.

### BRIEF DESCRIPTION OF THE DRAWINGS

FIG. 1 is a schematic configuration diagram of a semiconductor memory device according to an embodiment;

FIG. 2 is a schematic configuration diagram of the NAND flash memory shown in FIG. 1;

FIG. 3 is a diagram showing the count of “1”s in data read in distribution reading from the NAND flash memory;

FIG. 4 is a diagram showing difference (delta) data on the number of “1”s shown in FIG. 3;

FIG. 5 is an enlarged view of B level, C level, and D level in FIG. 4;

FIG. 6 shows a distribution of 8-level data;

FIG. 7 is an enlarged view of B level, C level, and D level in the distribution of FIG. 6;

FIG. 8 shows a distribution of D level shown in FIG. 7;

FIG. 9 shows an example of changing the initial value of the read level in the example of FIG. 7;

FIG. 10 shows an example of changing the initial value of the read level at D level;

FIG. 11 shows an example of changing the initial value of the read level at C level;

FIG. 12 shows an example of a search region for D level;

FIG. 13 shows an example of a search region for D level;

FIG. 14 shows an example of a search region for C level;

FIG. 15 is a flowchart to explain a distribution read operation;

FIG. 16 is a flowchart to explain the operation of creating a histogram on the basis the count of “1”s read in distribution reading;

FIG. 17 shows the count of “1”s read in distribution reading;

FIG. 18 shows difference data on the number of “1”s read in distribution reading;

FIG. 19 shows the weighted average of difference data of FIG. 18;

FIG. 20 is a flowchart to explain the operation of calculating weighted average;

FIG. 21 is an enlarged view of the proximity of D level of FIG. 8;

FIG. 22 shows the weighted average of graph of FIG. 21;

FIG. 23 is a flowchart to explain an example of the operation of searching for the minimum value;

FIG. 24 is a flowchart to explain another example of the operation of searching for the minimum value;

FIG. 25 shows an example of the bottom of a histogram getting wider in Vth tracking;

FIG. 26 shows another example of the bottom of a histogram getting wider in Vth tracking;

FIG. 27 shows an example of calculating the weighted average of the histogram shown in FIG. 25;

FIG. 28 shows an example of calculating the weighted average of the histogram shown in FIG. 26;

FIG. 29 is a flowchart to explain Vth tracking according to a first embodiment;

FIG. 30 is a flowchart to explain an example of a first search operation shown in FIG. 29;

FIG. 31 is a flowchart to explain an example of a second search operation;

FIG. 32 is a flowchart to explain an example of the operation of calculating a shift value;

FIG. 33 shows an example of a minimum value calculated with a general method;

FIG. 34 shows the optimum value of Vth calculated by a general method;

FIG. 35 shows an example of the number of “1”s included in data on Vth having changed due to the fluctuation of distribution reading;

FIG. 36 shows the minimum value, a case where the first embodiment is applied to the example shown in FIG. 33;

FIG. 37 shows a case where the first embodiment is applied to the example of FIG. 33, and shows the case where the threshold for searching for the bottom of distribution based on the minimum value has been set;

FIG. 38 shows a shift value calculated with the first embodiment is applied to the example shown in FIG. 33;

FIG. 39 is a diagram to explain a case where the first embodiment has been applied to the example of FIG. 35, showing the minimum value;

FIG. 40 shows a case where the first embodiment is applied to the example of FIG. 35, and a case where a threshold value has been set to search for the bottom of a distribution on the basis of the minimum value;

FIG. 41 shows a shift value obtained in the first embodiment regarding the example of FIG. 35;

FIG. 42 is a flowchart to explain Vth tracking according to a second embodiment;

FIG. 43 is a flowchart to specifically explain a first search operation shown in FIG. 42;

FIG. 44 is a flowchart to specifically explain a second search operation shown in FIG. 42;

FIG. 45 is a flowchart to explain Vth tracking according to a third embodiment;

FIG. 46 is a flowchart to specifically explain a first search operation shown in FIG. 45;

FIG. 47 is a flowchart to specifically explain a second search operation shown in FIG. 45;

FIG. 48 is a flowchart to explain the operation of calculating a shift value shown in FIG. 45;

FIG. 49 is a flowchart to explain a general operation of Vth tracking according to a fourth embodiment;

FIG. 50 is a flowchart to explain the first half of a first search operation shown in FIG. 49;

FIG. 51 is a flowchart to explain the second half of the first search operation shown in FIG. 49;

FIG. 52 is a flowchart to explain the first half of a second search operation shown in FIG. 49;

FIG. 53 is a flowchart to explain the second half of the second search operation shown in FIG. 49;

FIG. 54 is a flowchart to explain the operation of calculating a shift value shown in FIG. 49;

FIGS. 55A and 55B show examples of estimating Vth at the bottom of a distribution according to a sixth embodiment;

FIGS. 56A and 56B show other examples of estimating Vth at the bottom of a distribution according to the sixth embodiment;

FIGS. 57A and 57B show other examples of estimating Vth at the bottom of a distribution according to the sixth embodiment;

FIGS. 58A and 58B show other examples of estimating Vth at the bottom of a distribution according to the sixth embodiment;

FIGS. 59A and 59B show other examples of estimating Vth at the bottom of a distribution according to the sixth embodiment;

FIGS. 60A and 60B show other examples of estimating Vth at the bottom of a distribution according to the sixth embodiment;

FIGS. 61A and 61B show other examples of estimating Vth at the bottom of a distribution according to the sixth embodiment;

FIGS. 62A and 62B show other examples of estimating Vth at the bottom of a distribution according to the sixth embodiment;

FIGS. 63A and 63B show examples of estimating Vth at the bottom of a distribution on the assumption of a normal distribution;

FIGS. 64A and 64B show examples of estimating Vth at the bottom of a distribution in the vicinity of the distribution;

FIGS. 65A and 65B show cases where the Vth combinations of FIGS. 64A and 64B are interchanged;

FIGS. 66A and 66B show cases where the values of the histogram are interchanged and two straight lines are caused to cross each other;

FIGS. 67A and 67B are diagrams to explain an approximation in FIGS. 66A and 66B;

FIG. 68 is a diagram to explain a method of calculating an approximate equation that represents the values of the intersections on the horizontal axis shown in FIGS. 55A, 55B to 65A, 65B;

FIG. 69 is a table according to a seventh embodiment; and

FIG. 70 is a table according to an eighth embodiment.

### DETAILED DESCRIPTION

In general, according to one embodiment, a semiconductor memory device includes a memory and a controller. The memory includes a plurality of memory cells each of which stores data when one of an n number of threshold voltages (n being a natural number not less than two) is set. The controller reads data from the memory. The controller reads data from the memory cells at each of the threshold voltages in a read operation that checks a distribution of threshold voltages of the memory cells, calculates difference data on data read at each of the threshold voltages, calculates a minimum value of the distribution of the threshold voltages from the difference data, calculates a range of threshold voltages where the difference data are smaller than the upper limit value based on the minimum value, and sets a central voltage in the calculated range of threshold voltages as a read voltage.

Hereinafter, referring to the accompanying drawings, embodiments will be explained.

(Device Configuration)

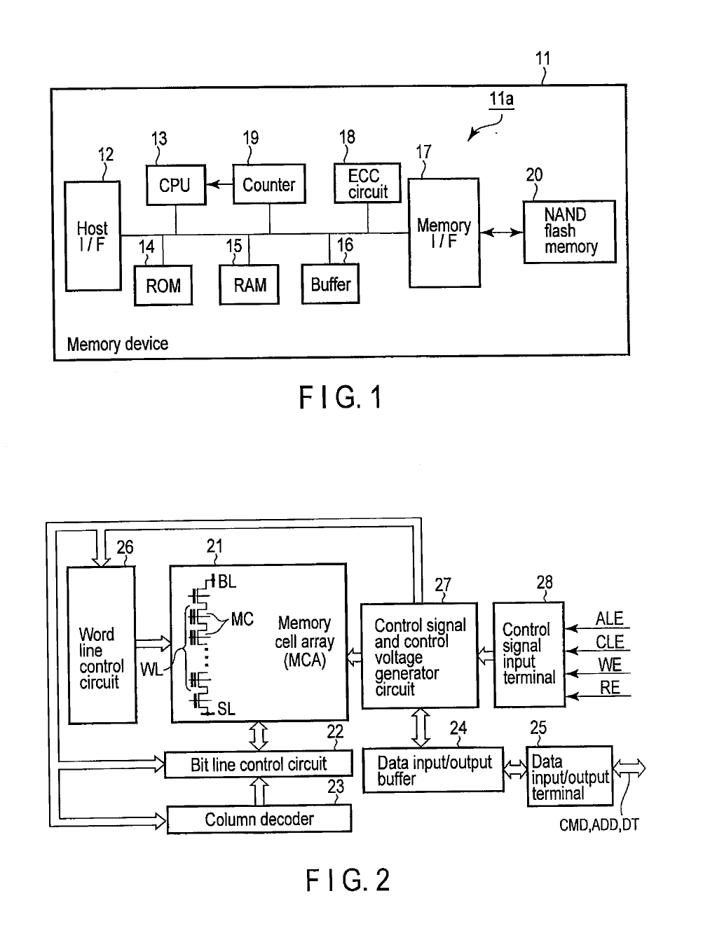

FIG. 1 schematically shows a semiconductor memory device according to an embodiment.

A semiconductor memory device 11 is used in, for example, an SD card. When being connected to a host device (not shown), the semiconductor device 11 is supplied with electric power and performs a process according to an access from the host device. The semiconductor memory device 11 includes a controller 11a.

The controller 11a comprises, for example, a host interface (I/F) 12, a CPU 13, a ROM (Read Only Memory) 14, a RAM (Random Access Memory) 15, a buffer 16, a memory interface (I/F) 17, an error correction circuit (ECC circuit) 18, and a counter 19. These are connected to one another with a bus. To the memory interface 17, for example, a NAND flash memory 20 is connected.

The host interface 12 performs an interface process between the controller 11a and the host device.

The memory interface 17 performs an interface process between the controller 11a and the NAND flash memory 20.

The CPU 13 supervises the operation of the entire memory device 11. The CPU 13 receives, for example, a write command, a read command, or an erase command from the host and accesses an area on the NAND flash memory 20 or controls a data transfer process via the buffer 16.

The ROM 14 stores firmware, such as a control program used by the CPU 13. The RAM 15, which is used as a work area of the CPU 13, stores a control program and various tables.

The buffer 16 stores a specific amount of data (e.g., one page of data) temporarily when writing data sent from the host into, for example, the NAND flash memory 20 or when sending data read from the NAND flash memory 20 to the host device.

The ECC circuit 18 corrects an error in data read from the NAND flash memory 20.

When performing distribution reading described later, the counter 19 is used to count the number of “1”s included in data read from the NAND flash memory 20 in order to obtain a histogram of a threshold voltage distribution.

The NAND flash memory 20, which is composed of, for example, stacked-gate-structure memory cells or MONOS-structure memory cells, is capable of storing multivalued data, for example, 8-value data (also referred to as 8-level data).

FIG. 2 shows a schematic configuration of the NAND flash memory 20.

A memory cell array 21 includes a plurality of bit lines BLs and a plurality of word lines WLs and a common source line SL, with a plurality of electrically rewritable memory cells, such as EEPROM cells, constituting NAND strings. A bit line control circuit 22 for controlling bit lines and a word line control circuit 26 are connected to the memory cell array 21.

The bit line control circuit 22 reads data in a memory cell in the memory cell array 21 via a bit line, detects the state of a memory cell in the memory cell array 21 via a bit line, or applies a write control voltage to a memory cell in the memory cell array 21 via a bit line to write data into the memory cell. A column decoder 23 and a data input/output buffer 24 are connected to the bit line control circuit 22. A data memory circuit in the bit line control circuit 22 is selected by the column decoder 23. Data in a memory cell read by the data memory circuit is output via the data input/output buffer 24 at a data input/output terminal 25 to the outside. Externally supplied various commands CMDs that control the operation of the NAND flash memory, addresses ADDs, and data DT are input to the data input/output terminal 25. Write data input to the data input/output terminal 25 is supplied via the data input/output buffer 24 to the data memory circuit selected by the column decoder 23. Commands and addresses are supplied to a control signal and control voltage generator circuit 27.

The word line control circuit 26 is connected to the memory cell array 21. The word line control circuit 26 selects a word line in the memory cell array 21 and applies a voltage necessary for reading, writing, or erasing to the selected word line.

The memory cell array 21, bit line control circuit 22, column decoder 23, data input/output buffer 24, and word line control circuit 26 are connected to the control signal and control voltage generator circuit 27 and are controlled by the control signal and control voltage generator circuit 27. The control signal and control voltage generator circuit 27 is connected to a control signal input terminal 28 and is controlled by control signals ALE (Address Latch Enable), CLE (Command Latch Enable), WE (Write Enable), and RW (read Enable) which are externally input via the control signal input terminal 28.

The bit line control circuit 22, column decoder 23, word line control circuit 26, and control signal and control voltage generator circuit 27 constitute a write circuit and a read circuit.

The control signal and control voltage generator circuit 27 includes a digital-analog converter (not shown). The digital-analog converter generates a read voltage in a read operation or a program voltage in a write operation on the basis of predetermined numeric data. For example, when eight-level data items, i.e. erase level data item, A level data item, B level data item, C level data item, D level data item, E level data item, F level data item, and G level date item, have been stored in a memory cell in ascending order, numeric data items necessary to read data at A level, B level, C level, D level, E level, F level, and G level are previously set. Hereinafter, numeric data items input to the digital-analog converter are referred to as nDAC (n being a numeric value). Numeric data items for reading A level to G level are set to, for example, 25DAC, 90DAC, 140DAC, 220DAC, 300DAC, 370DAC, and 420DAC, respectively. These numeric data items are stored in, for example, a data region for a controller of the memory cell array 21. When power is turned on, the numeric data items are read from the memory cell array 21 and transferred to a register (not shown). The control signal and control voltage generator circuit 27 generates a required read voltage on the basis of numeric data items held in the register in a read operation. Hereinafter, the erase level, A level, B level, C level, D level, E level, F level, and G level are generically called Read level.

As described above, when stress is applied to a NAND flash memory or when a long time has elapsed since data was written, the threshold voltage (hereinafter, also referred to as a Vth level) of each memory cell varies. Therefore, when data is read from the memory cell, the data cannot be read accurately from the memory cell on the basis of a read voltage generated based on the preset numeric data. As a result, the bit error rate, the rate of the number of error bits included in the read data, increases. When the Vth level is shifted, this enables errors to be remedied to some extent by adding error correction code (ECC) to the errors. However, the optimization of a read voltage in reading data from a memory cell enables the bit error rate of data before correction by ECC to be decreased remarkably. As a result, the error correction time at the ECC circuit can be made shorter and the power consumption of the ECC circuit can be suppressed.

When the read voltage of a memory cell is optimized, the distribution of Vth levels of memory cells needs to be searched for. Therefore, the controller 11a has a distribution read function, described later, to search for the threshold voltage distribution of memory cells.

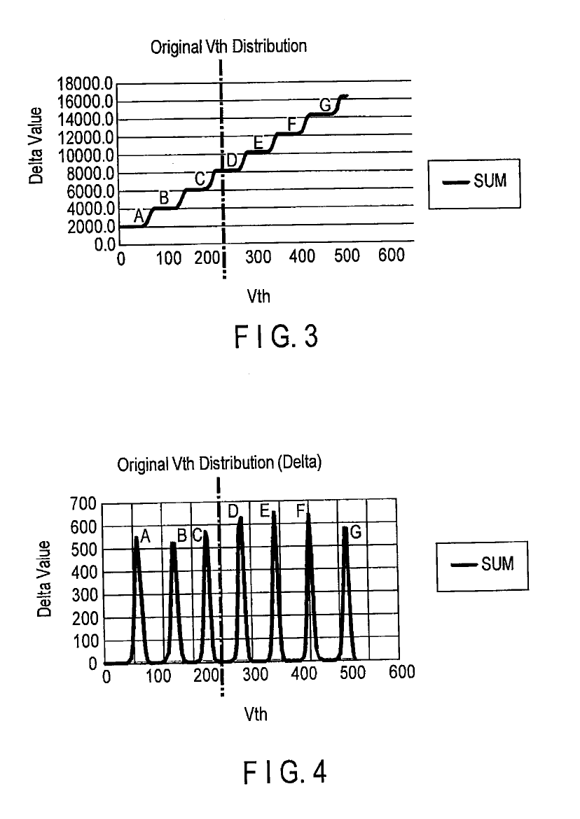

FIGS. 3, 4, and 5 show examples of Vth levels immediately after data was written into an eight-level NAND flash memory having been read in distribution reading.

FIG. 3 is a diagram showing the count of “1”s in data read in distribution reading, with the vertical axis representing counts and the horizontal axis representing Vth levels by numeric data input to the digital-analog converter. In FIG. 3, since a Vth distribution at the erase level is not shown as a graph because Vth is not higher than “0.”

FIG. 4 shows that the difference of the number of “1”s on the vertical axis shown in FIG. 3 is plotted in units of 4DAC on the horizontal axis. FIG. 4 shows a graph on the assumption of a normal distribution that disperses in left-right asymmetry with respect to the center of the distribution of data at each Vth level. In FIG. 4, a Vth distribution at the erase level is not shown as a graph because Vth is not higher than “0.” A part where values of the graph remain unchanged in FIG. 3 appears as “0” in FIG. 4. A part where the slope is sharper in the graph of FIG. 3 has a larger value in FIG. 4.

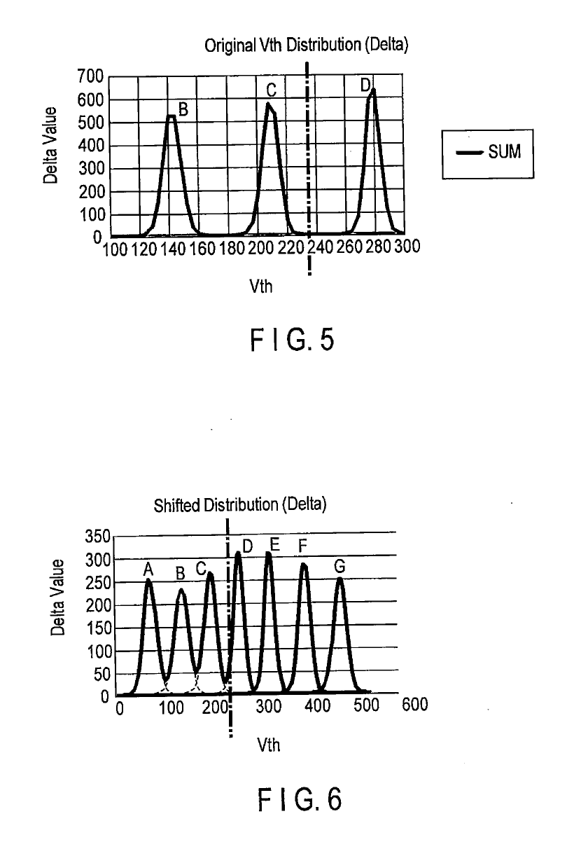

FIG. 5 is an enlarged view of B level, C level, and D level in FIG. 4.

A broken line in each of FIGS. 3, 4, and 5 indicates an initial read voltage (Vth=228DAC) at D level.

As shown in FIGS. 4 and 5, data at each level concentrates around the midpoint of the Read level immediately after writing. For example, when reading is done at D level, 228DAC is set as a read voltage. If the Vth level of a memory cell is lower than the read level, data in the memory cell is read as “1.” If the Vth level is higher than the read level, data in the memory cell is read as “0.” In the case of FIG. 5, data “1” is read from the memory cell at which the Vth level is lower than 228DAC.

Each of FIGS. 6, 7, and 8 shows an example of the center of data at each level written as shown in FIGS. 4 and 5 being shifted about 6 to 8DAC to the negative side, with the dispersion increased.

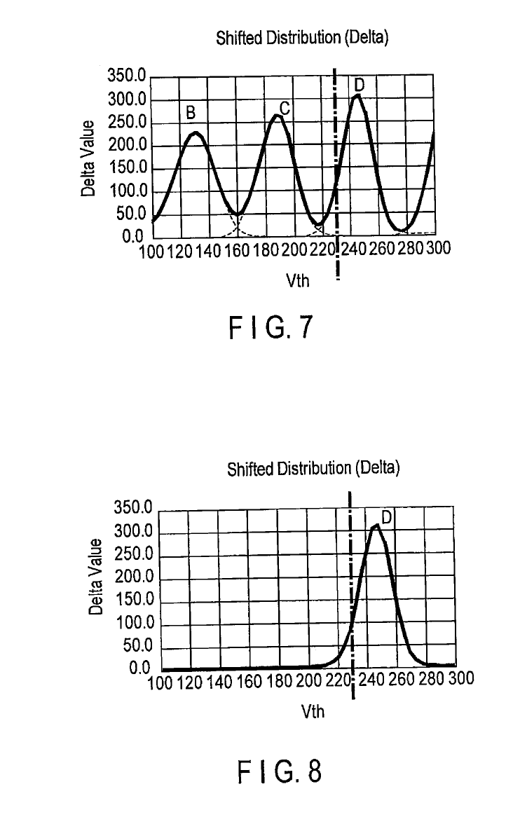

Like FIG. 4, FIG. 6 shows all the distributions of data at eight levels. FIG. 7 is an enlarged view of the distributions of B level, C level, and D level in FIG. 6. FIG. 8 shows only the distribution of data written at D level in FIG. 7.

It is seen from FIGS. 6, 7, and 8 that data written at D level is subjected to stress and from the distributions in FIGS. 4 and 5 that the data is shifted to the negative side. A region represented by the area on the left side of Vth level=228DAC and under a normal distribution curve data is shifted from D level to C level. When data is read at an initial value of D level, Vth level=228DAC, a part corresponding to the area on the left side of the vertical broken line and under the normal distribution curve in FIG. 8 is read as C level, not D level. Therefore, data supposed to be read as “0” is read as “1” erroneously.

Data obtained by writing, at D level, the result of dividing the area on the left side of the broken line and under the normal distribution curve in FIG. 8 by the entire area under the normal distribution curve in FIG. 8 is an error rate in being read as data at C level (more properly, an error rate in being read as data at the erase level, A level, B level, or C level lower than D level).

As described above, ECC or shift reading is used as the technique for reducing errors by reading at a level differing from a preset read voltage when the Vth level of a memory cell has been shifted. The memory controller 11a combines ECC with shift reading to output correct data. ECC corrects erroneous read data to obtain correct data.

On the other hand, shift reading changes the read voltage, thereby reducing the error rate of read data itself. Specifically, as shown in FIG. 8, if the center of D level has been shifted −8DAC, shifting a read level at D level about −8DAC can minimize the total number of errors which include the cases where the data written at D level are read at C level and the cases where the data written in C level are read at D level, thereby enabling the total error rate to be reduced.

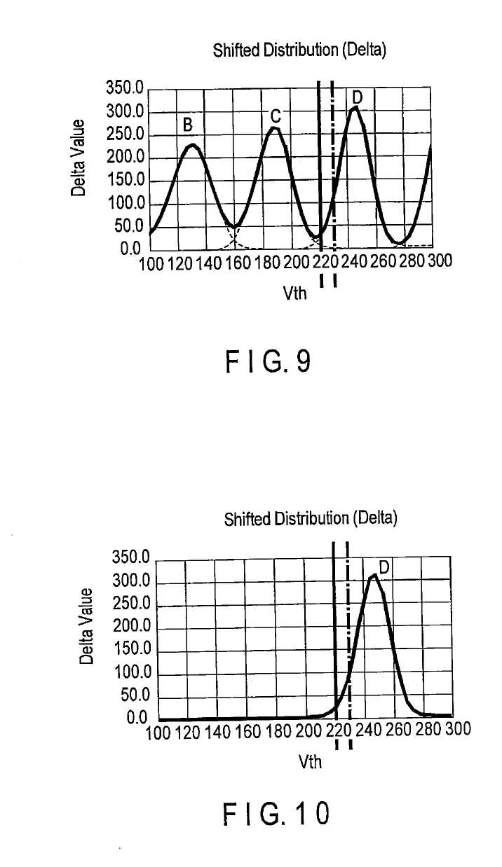

FIGS. 9, 10, and 11 show a case where the initial value of read level has been set to 220DAC by shifting the initial value from 228DAC by −8DAC in the same example as in FIGS. 6 and 7.

In FIG. 10, when attention is focused on D level, shifting the read level from 228DAC to 220DAC causes the area on the left side of a read level of 220DAC and under the normal distribution curve to decrease. This corresponds to a decrease in the number of errors. When only D level is taken into account, errors can be decreased further by lowering the read level more. However, when attention is focused on C level, shifting the read level at D level from 228DAC to 220DAC causes the area on the left side of a read level of 220DAC and under the normal distribution curve to increase. That is, shifting the read level to the negative side enables errors of shifting D level to C level to be decreased, but causes errors of shifting C level to D level to increase. According to the characteristic of a normal distribution, the number of errors distributed decreases as the distance from the center gets larger. Therefore, when the read level is shifted, there is an “optimum value” at which a decrease in the number of errors of mistaking D level for C level coincides with an increase in the number of errors of mistaking C level for D level.

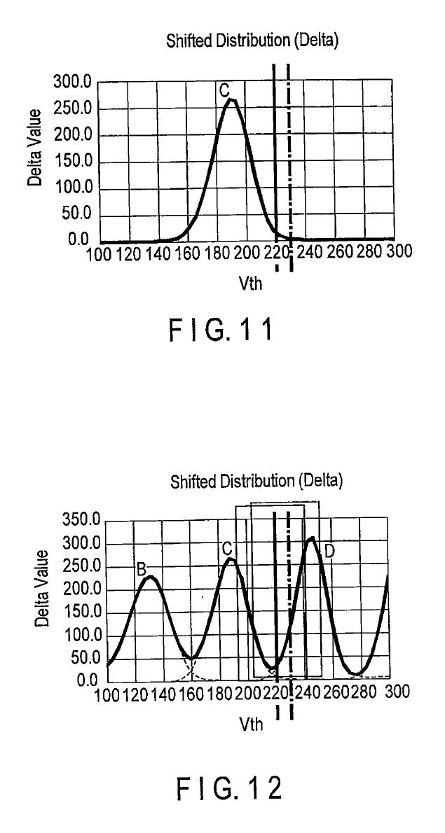

The embodiment minimizes the error rate of data read in shift reading with the shifted read voltage. That is, in the embodiment, the optimum value of the read voltage is searched for. In a read operation of an actual NAND flash memory, since a memory cell supposed to be at D level (corresponding to FIG. 10) and a memory cell supposed to be at C level (corresponding to FIG. 11) cannot be distinguished from each other, except for a special case, the optimum value of the read level has to be searched for from a curve obtained by adding up FIGS. 10 and 11, that is, a curve shown in FIG. 9.

A series of operations of searching for the optimum value of the read level is called Vth tracking. In Vth tracking, to search for the optimum value of Vth, “distribution read” installed as a command in the NAND flash memory is executed.

“Distribution read” reads a specific amount of data in a two-level mode (SLC mode), while changing the read level in units of a specific amount. The controller 11a provides a search region centering on each Vth level of the NAND flash memory to save the memory capacity used for programs and often performs distribution reading at each Vth level.

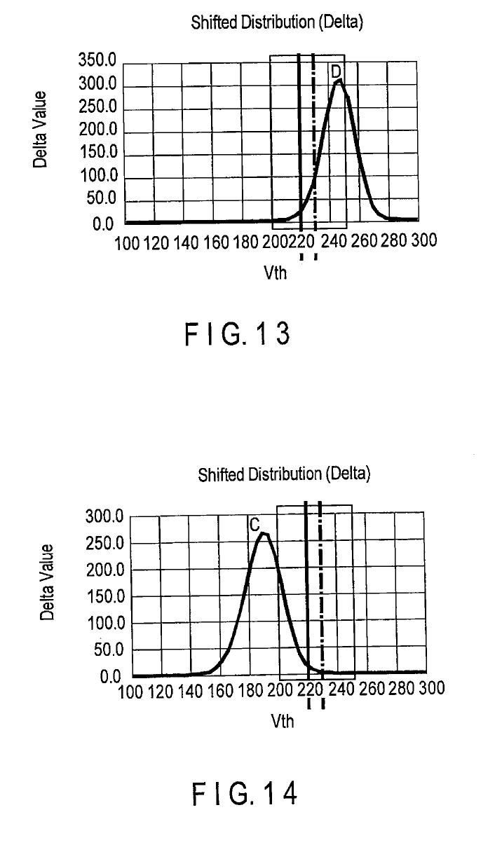

FIGS. 12, 13, and 14 each show an example of the search region for D level and C level in a rectangle. In the example, the initial value of the read level at D level is set to 228DAC. In FIGS. 12, 13, and 14, an effective search region is set to not less than 200DAC nor more than 248DAC.

(Distribution Read)

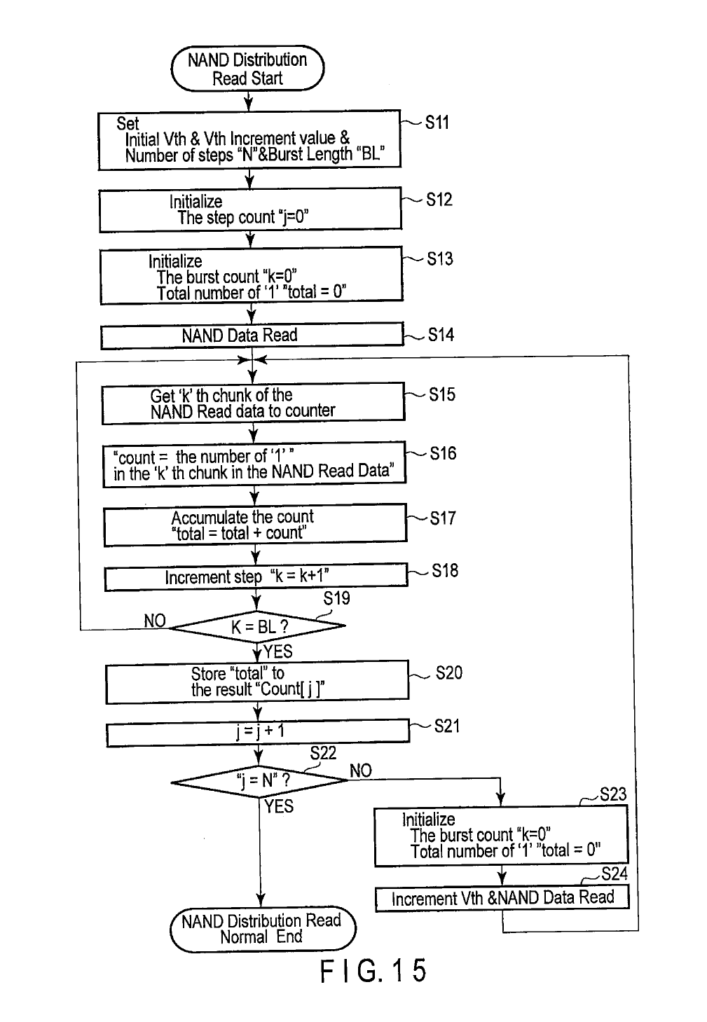

FIG. 15 is a flowchart to explain a distribution read operation at a Read level.

In the controller 11a, a start level of distribution reading, that is, nDAC (an initial read level (Vth)), an increment in Vth, the number of steps N (N being the total number of Vth levels at which distribution reading is performed at the currently watched Read level), and a burst length BL are set (S11). In addition, the step count is initialized to “j=0” (S12), the burst count is initialized to “k=0,” the count of “1”s “total” is initialized to “0” (S13). In this state, distribution reading is started (S14). Specifically, the NAND flash memory 20 reads a predetermined data amount, for example, 1 k bytes or 16 k bytes of data, and transfers the data in units of, for example, one byte to the controller 11a via the memory interface 17.

The controller 11a counts the number of “1”s included in one byte of data as long as a burst length (S15, S16, S17, S18, S19). The count is done by the counter 19 shown in FIG. 1. The count may be done by software in place of the counter 19.

When the number of “1”s has been counted as long as the burst length, the count of “1”s “total” is stored together with the Vth level into (Count [j]) (S20).

Thereafter, step count “j” is updated to step up the Vth level (S21) and it is determined whether all the Vth levels have been read (S22). If the determination result has shown that all the Vth levels have not been read, the burst count and the count of “1”s “total” is reset (S23), the Vth level is updated, and distribution reading is started (S24).

After this, the above operations are repeated. When the number of “1”s included in data output from the NAND flash memory 20 has been counted as long as the burst length (S15, S16, S17, S18, S19), the count of “1”s “total” is stored together with the Vth level into (Count [j])ni (S20).

As described above, the processes of stepping up the Vth level, performing distribution reading, and counting the number of “1”s included in the data are repeated until the value of step count “j” has reached “N” (S21, S22).

The step-up DAC value of each distribution read can be specified, depending on the NAND flash memory 20. If the step-up DAC value cannot be specified, the DAC value corresponding to the read level is sent to the NAND flash memory 20 in the second step and forward.

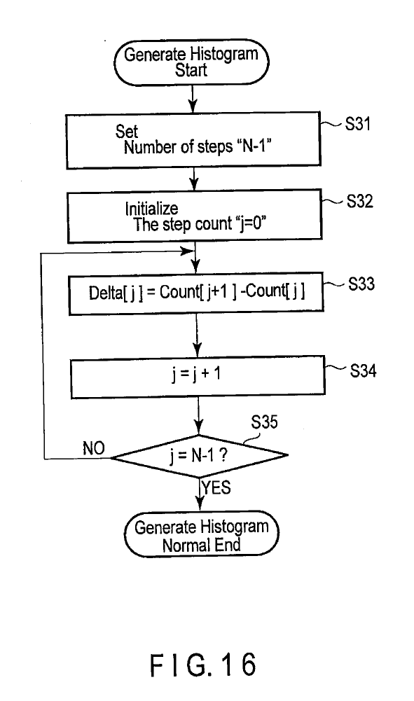

When it has been determined in step S22 that the value of step count “j” has reached “N,” control is passed to FIG. 16.

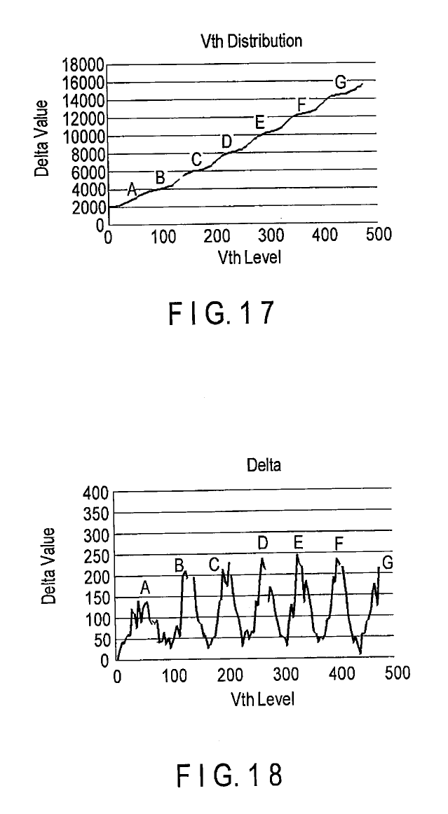

The Vth level is plotted on the horizontal axis and the number of “1”s is plotted on the vertical axis on the basis of the result of distribution reading, thereby giving a graph shown in FIG. 17.

(Histogram Creation)

FIG. 16 is a flowchart to explain the operation of creating a histogram on the basis of the number of “1”s counted at each Vth level shown in FIG. 17.

The controller 11a calculates the difference (delta) between the count of “1”s (Count(j)) at a VTh level and the count of “1”s (Count(j+1)) at an adjacent Vth level. Therefore, as shown in FIG. 16, the number of steps is set to “N−1” (S31) and the step count is initialized to “j=0” (S32). Thereafter, equation (1) is calculated, while step count “j” is being updated, until the step count has reached “N−1” (S33, S34, S35):

Delta[j]=Count[j+1]−Count[j] (1)

In this way, the difference in the count of “1”s (Delta (j)) is found. The Vth level is plotted on the horizontal axis and the difference (Delta (j)) in the count of “1”s is plotted on the vertical axis, giving a histogram shown in FIG. 18.

As seen from the above operations, it is desirable that the number of “1”s present at each Vth level should be almost the same to search for the optimum value of the read level. Generally, a method of writing randomized data to increase the reliability of data written into the NAND flash memory 20 has been applied to the memory controller 11a. Therefore, in the embodiment, too, it is desirable that data in the NAND flash memory 20 should be randomized to make the number of “1”s present at each Read level almost the same. However, even if data has not been randomized, the embodiment can be applied.

In the NAND flash memory, it is known that, even if the same Vth level has been specified, obtained histograms do not necessarily coincide with one another because of a fluctuation in the Vth actually set at a set Vth level or stress applied to the memory cell due to the act of examining a Vth distribution, that is, histograms themselves fluctuate.

FIGS. 17, 18, and 19 show histograms obtained by performing Vth tracking on an actual 8-level NAND flash memory.

FIG. 17 is a graph showing the number of “1”s in data read from the NAND flash memory with respect to DAC values corresponding to the individual Vth levels set in distribution reading on the horizontal axis.

FIG. 18 is a graph obtained by dividing the horizontal axis of FIG. 17 in steps of 4DAC, plotting a difference calculated for each step on the vertical axis, and indicating DAC values corresponding to the individual Vth levels on the horizontal axis.

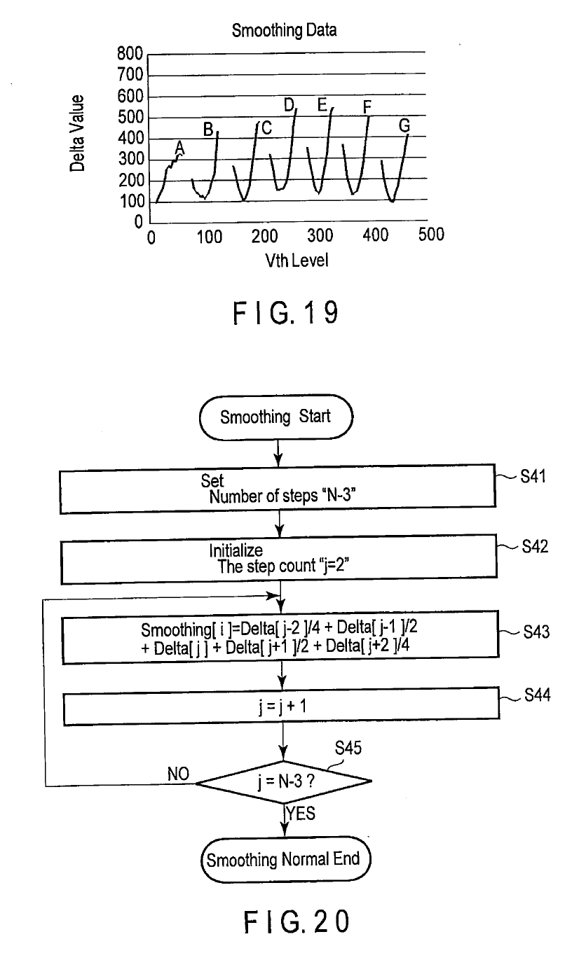

FIG. 19 is a graph obtained by calculating a weighted average of the values on the graph of FIG. 18 as described later and then smoothing the graph.

When distribution reading is performed on an actual NAND flash memory, a nonsmooth graph might be obtained as shown in FIG. 18. To alleviate the effect of the fluctuation, a weighted average of values of a histogram at Vth levels may be calculated by using several steps in front of and behind a histogram value (Delta (j)) at which a Vth level corresponds to j, thereby reducing the effect of a fluctuation in the histogram. when a weighted average of two steps in front of and behind the histogram value is calculated so as to halve the effect each time, for example, a Vth level is separated by one step, a value (Smoothing (j)) at each Vth=j of the histogram after the weighted average is represented by equation (2):

$$Smoothing [ j ] = Delta [ j - 2 ] / 4 + Delta [ j - 1 ] / 2 + Delta [ j ] + Delta [ j + 1 ] / 2 + Delta [ j + 2 ] / 4 \qquad ( 2 )$$

(Weighted Average)

FIG. 20 is a flowchart for calculating the weighted average. In FIG. 20, first, the number of steps is set to “N−3” (S41), the step count is initialized to “j=2” (S42), and equation (2) is calculated (S43). Thereafter, step count j is updated (S44) and the calculation in step S43 is repeated until the number of steps has reached “N−3” (S45).

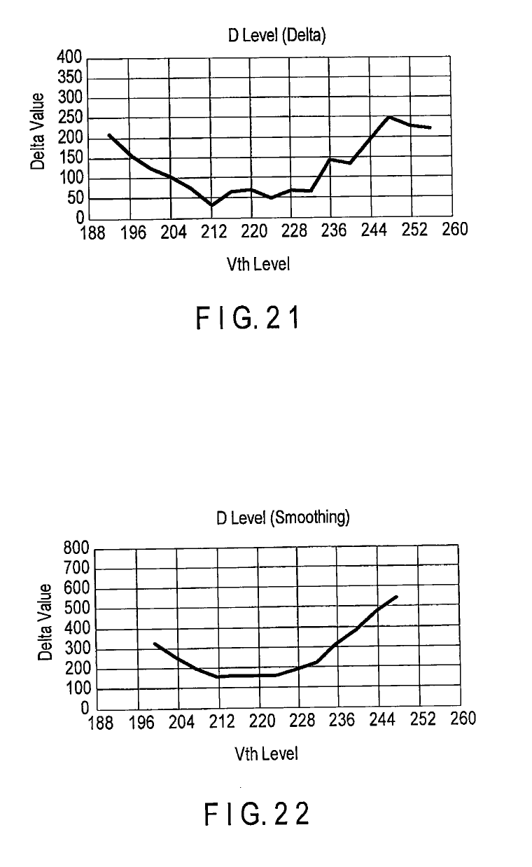

FIG. 21 is a graph where a part near D level in FIG. 18 is enlarged. A weighted average of the fluctuated histogram is calculated, producing a smoothed histogram as shown in FIG. 22.

(General Minimum Value Search)

In a general minimum value search, a point (Vth_shifted(Level)) at which a weighted average histogram (Smoothing (i)) as shown in FIG. 22 takes the minimum value is determined to be the bottom (concave part) of each Vth level and the delta between the bottom (Vth_shifted(Level)) of the Vth level and the initial value (Vth_init(Level)) of the Vth level is determined to be a shift value (VthShift(Level)) at the Vth level (Level) using equation (3):

$$VthShift ( Level ) = Vth\_shifted ( Level ) - Vth\_init ( Level ) \qquad ( 3 )$$

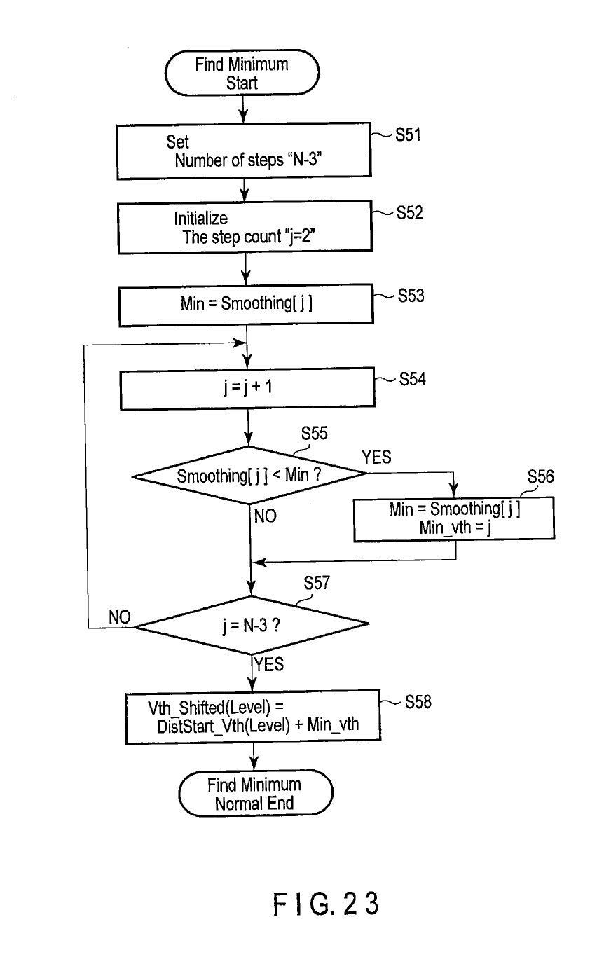

FIG. 23 is a flowchart for searching for minimum value Vth_shifted(Level) when the DAC value of the start Vth level in distribution reading is set to DistStart_Vth(Level).

In FIG. 23, first, the number of steps “N−3” is set (S51) and the step count is initialized to “j=2” (S52). Thereafter, the value (Smoothing (j)) of Vth=j of the weighted average histogram is set as minimum value Min and the value of step count j is set to Min_Vth (S53).

Next, step count “j” is updated (S54) and (Smoothing (j)) is compared with minimum value Min (S55). If (Smoothing (j)) is smaller than minimum value Min, (Smoothing (j)) is set as minimum value Min (S56). This operation is repeated until step count “j” is updated and the updated step count “j” has reached the number of steps “N−3” (S57 to S54).

When it has been determined in step S57 that the step count “j” has reached the number of steps “N−3,” the DAC value DistStart_Vth(Level) of the start Vth in distribution reading is added to Min_Vth, thereby calculating Vth_Shifted(Level) which gives Vth of minimum value when the DAC value of the start Vth in distribution reading is set as DistStart_Vth(Level) (S58).

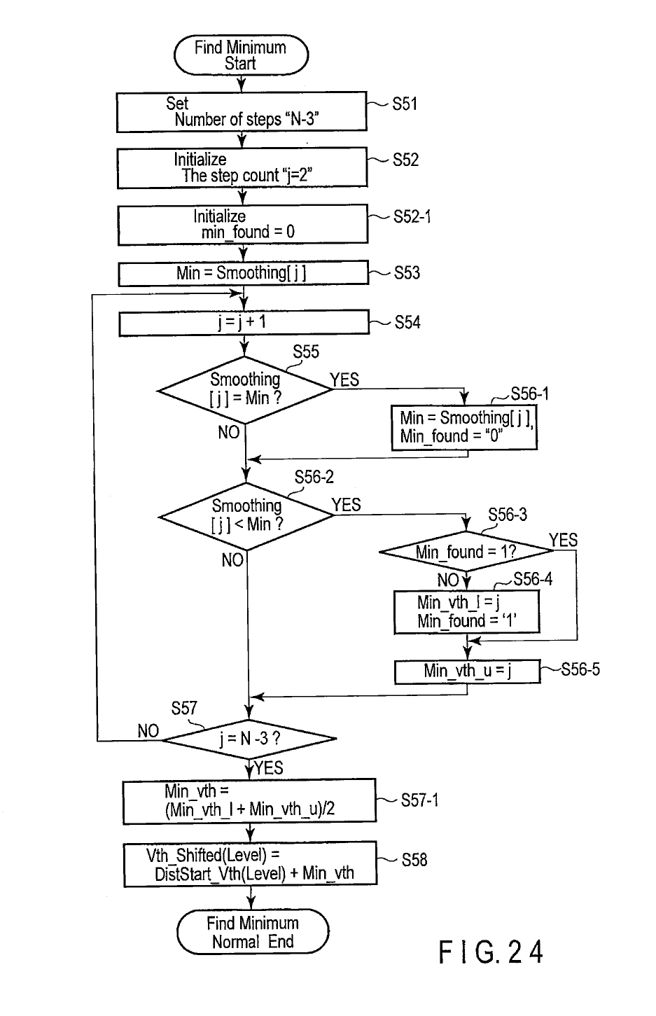

FIG. 23 shows a method of detecting Vth at which difference data takes the minimum value when the Delta value takes the minimum value only at a Vth. However, when a Vth where difference data takes the minimum value has a width, the center value (average value) of the Vth where the difference data takes the minimum value can be obtained by the operations as shown in FIG. 24.

In FIG. 24, the same parts as those in FIG. 23 are indicated by the same reference numerals and only what differs from FIG. 23 will be explained. In this example, there is provided flag min_found which is to be set when a Vth at which difference data takes the minimum value has been detected. In the initial setting, the flag min_found is reset (S52-1). Thereafter, the minimum value is searched for (S53 to S55). When the minimum value has been detected (S56-1, S56-2), it is determined whether flag min_found has been set (S56-3). If flag min_found has not been set, flag min_found is set and the value j of a Vth at which difference data takes the minimum value is held in Min_vth_l and flag min_found is reset (S56-4). In addition, the value j of the Vth is held in Min_vth_u (S56-5).

Thereafter, the value of step count “j” is updated and the above operations are repeated until the number of steps “N−3” has been reached (S57 to S54).

When the value of step count “j” has reached the number of steps “N−3,” average value Min_vth of the minimum value is calculated using equation (4) (S57-1):

Min_vth=(Min_vth_{—}l−Min_vth_{—}u)/2 (4)

Furthermore, Vth_Shifted(Level) giving Vth of minimum value, when the DAC value of a start Vth in distribution reading is set as DistStart_Vth(Level), is calculated using equation (5):

VthShift(Level)=DistStart_Vth(Level)+Min_vth (5)

When the distribution of a weighted average histogram is narrow, this method is not problematic. However, if the distribution of the histogram is wide, the number of data in a region whose value is close to the minimum value of the value (Vth_shifted(x)) of a weighted average histogram near “the bottom of the distribution” might get larger. Therefore, a fluctuation in the weighted average histogram causes the value of VthShift(Lelel) to fluctuate, with the result that the bit error rate when data is read using this shift value is also unstable, causing a problem.

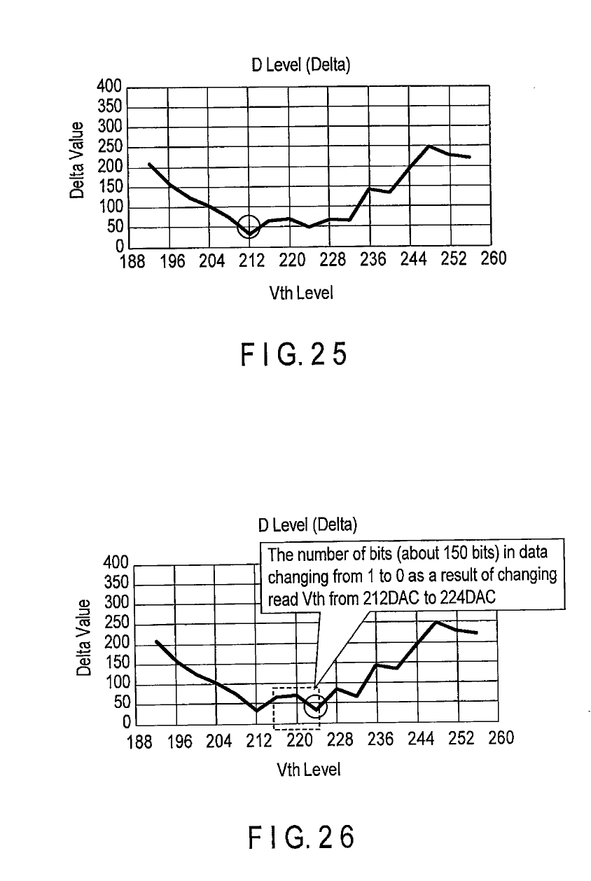

Examples of the bottom of the histogram having become wider as a result of Vth tracking performed on an actual NAND flash memory are shown in FIGS. 25 to 28.

FIG. 25 shows data on the difference at D level. FIG. 26 is a graph with the number of “1”s included in data with Vth=224DAC which is 15 less than data with Vth=224DAC of FIG. 25. The histogram of FIG. 25 presents the minimum value at 212DAC, whereas the histogram of FIG. 26 presents the minimum value at 224DAC.

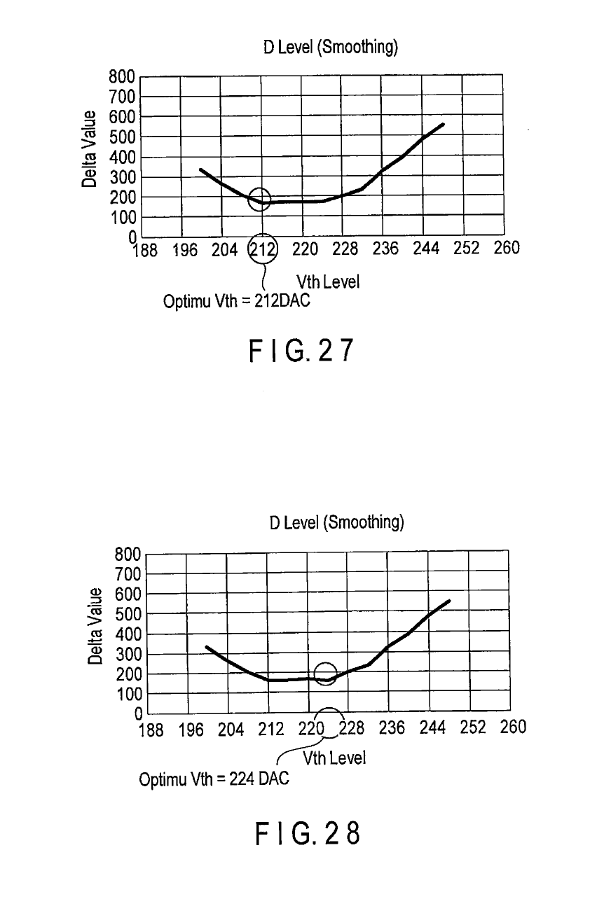

FIG. 27 shows a histogram obtained by calculating a five-point weighted average of the histogram of FIG. 25. FIG. 28 shows a histogram obtained by calculating a five-point weighted average of the histogram of FIG. 26.

In FIG. 27, a histogram takes the minimum value at 212DAC, whereas, in FIG. 28, a histogram takes the minimum value at 224DAC. That is, when the number of “1”s in data with Vth=226DAC fluctuates by 15, this causes the position of Vth at the bottom of the distribution obtained by Vth tracking to change from 212DAC to 224DAC by 12DAC. Since the number of “1”s changes by about 50 near Vth=212 to 224DAC in each step (4DAC) of distribution reading, if the optimum value of Vth changes by 12DAC, data read at each Vth will change by about 50 bits*3=about 150 bits. The difference in the number of error bits between the setting of Vth=212DAC and the setting of Vth=224DAC corresponds to an area under the graph enclosed by a broken line near 220DAC shown in FIG. 26.

As described above, when the bottom of the distribution has widened, if the number of “1”s included in data near the bottom of the distribution changes by about 15, the position of the optimum value at the bottom of the Vth changes significantly, with the result that the number of error bits fluctuates significantly. Therefore, when the distribution has widened, a problem arises: such a method permits the optimum value of Vth in Vth tracking to fluctuate and the chances are high even if use of powerful ECC that has the capability of correcting about 100 bits per 1 kB cannot correct errors.

### First Embodiment

To overcome the problem, a first embodiment makes two searches to find the minimum value from a histogram obtained by laying, side by side, weighted average data items in DAC units of Vth. Specifically, in a first search, the minimum value of a histogram is found, but a DAC value that takes the minimum value is not found. In a second search, a predetermined margin is added to the minimum value found in the first search to create a threshold value for a search and the minimum value and maximum value of the DAC value that becomes smaller than the threshold value in the histogram are searched for. The average value of the maximum value and minimum value of the DAC value detected in the second search is determined to be a DAC value at the bottom of the histogram. From the DAC value, the optimum value of Vth is found.

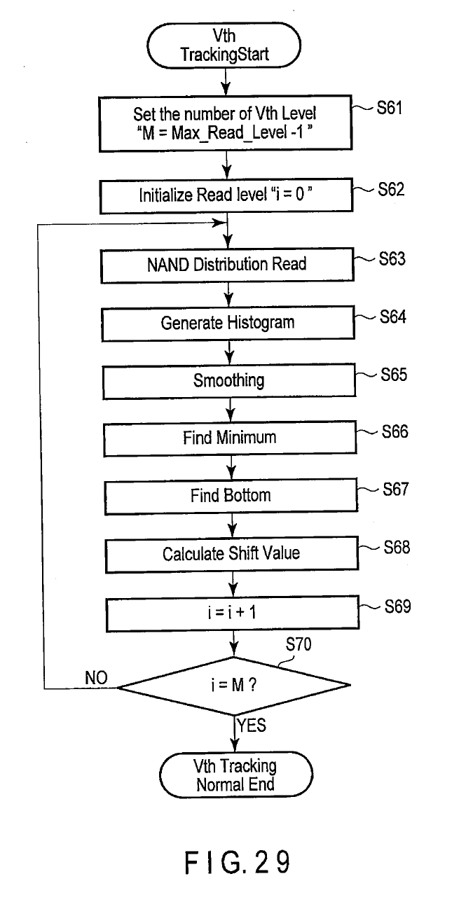

FIG. 29 is a flowchart to explain Vth tracking according to the first embodiment. Vth tracking according to the first embodiment will be explained with reference to FIG. 29.

First, the number of Vth levels is set to “M,” for example, “Max_Read_level−1” (S61) and Read level “i” is initialized to “0” (S62). In this state, distribution reading is performed on the NAND flash memory 20 at each Read level (S63). The distribution read operation is as shown in FIG. 15. The number of “1”s is counted at each Vth level.

Thereafter, the operation shown in FIG. 16 is executed, calculating the difference between the number of “1”s at a Vth level and the number of “1”s at an adjacent Vth level and creating a histogram on the basis of Delta data (Delta value) and Vth levels (S64).

Next, the operation shown in FIG. 20 is executed, calculating a weighted average of difference data and creating a weighted average histogram (S65).

Then, a first search operation for searching for a local part of the histogram of weighted average values, for example, “the minimum value”, is performed (S66).

(First Search Operation)

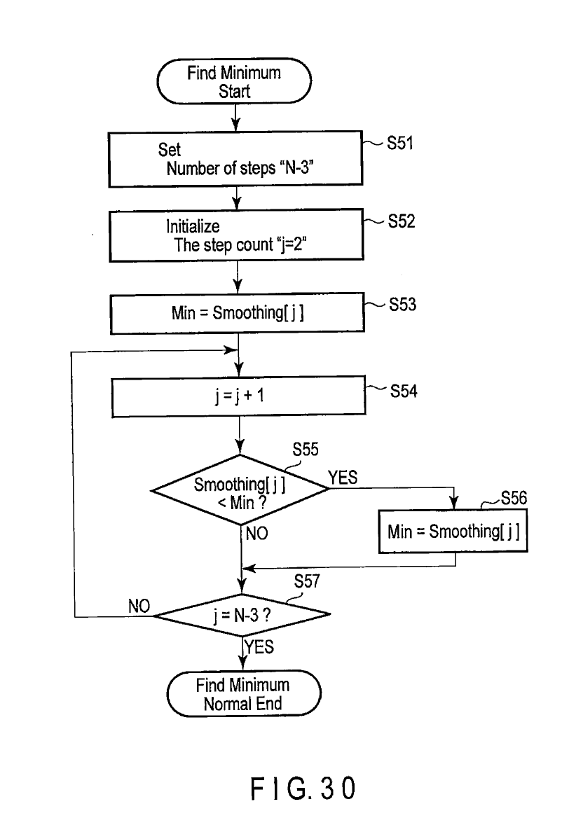

FIG. 30 is a flowchart to explain a first search operation. In FIG. 30, the same parts as those of FIG. 23 are indicated by the same reference numerals. In the first search operation, only one “minimum value” of a histogram is detected by the same operation as in FIG. 23. However, in this case, there is no need to store a DAC value corresponding to a Vth level at which difference data takes the minimum value at the minimum value search stage. That is, FIG. 30 differs from FIG. 23 in that step S58 of FIG. 23 is eliminated.

Next, a predetermined “margin,” for example, 15, is added to “the minimum value” obtained in the first search operation to create “a threshold value at the bottom of the distribution” and then a second search operation of searching for a range where a weighted average histogram takes a value smaller than the threshold value at the bottom of the distribution, that is, a region of the bottom of the distribution, is executed (S67). In the second search operation, one maximum value and one minimum value of Vth in the region of the bottom of the distribution are detected. Moreover, in the second search operation, an average value of the maximum value and minimum value of Vth at the bottom of the distribution is calculated.

(Second Search Operation)

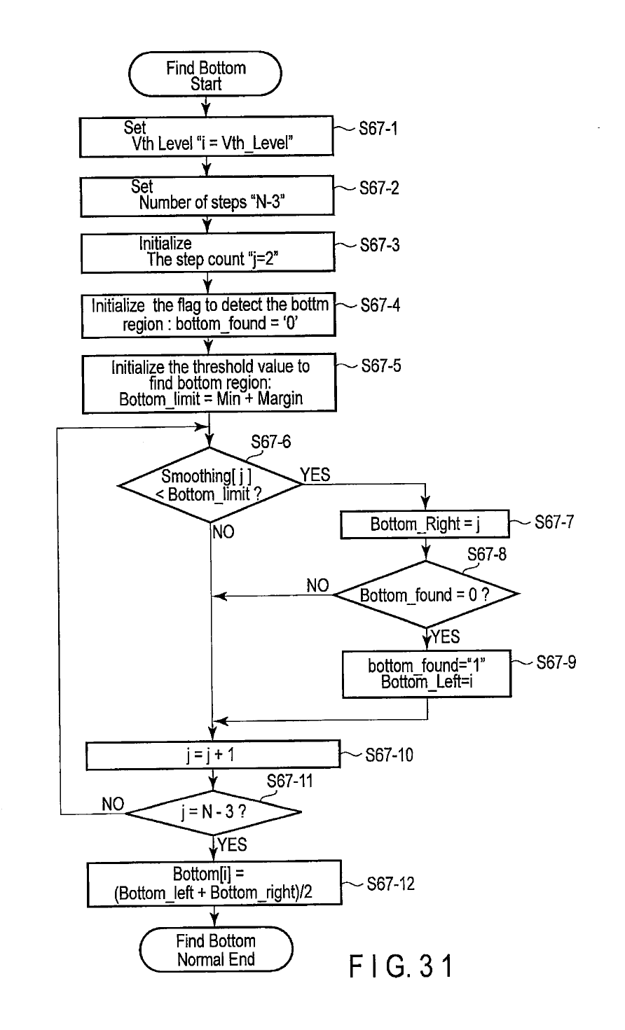

FIG. 31 is a flowchart to explain an example of a second search operation. First, Vth level “i” is set to a Vth level (S67-1), the number of steps is set to “N−3” (S67-2), step count “j” is set to “2” (S67-3), and flag bottom_found for detecting the region of the bottom of the distribution is set to “0” (S67-4). In addition, as described above, a predetermined margin Margin, for example, 15, is added to minimum Min obtained in the first search to create threshold value Bottom_limit at the bottom of the distribution (S67-5).

In this state, it is determined whether value Smoothing [j] of the smoothed histogram is smaller than Bottom_limit (S67-6). If the result has shown that value Smoothing [i] of difference data is smaller than Bottom_limit, the value of step count “j” is set in Bottom_Right as the maximum value of Vth in the region of the bottom of the distribution (S67-7).

Next, it is determined whether flag bottom_found is at “0” (S67-8). If flag bottom_found is at “0,” flag bottom_found is set at “1” and the value of step count “j” is set in Bottom_Left as the minimum value of Vth in the region of the bottom of the distribution (S67-9).

Thereafter, the value of step count “j” is updated and the above operations are repeated (S67-10, S67-11 to S67-6). When the value of step count “j” has reached “N−3,” average value Bottom [i] of Bottom_Left and Bottom_Right is calculated using equation (6):

Bottom[i]=(Bottom_Left+Bottom_Right)/2 (6)

After the “second search,” a shift value is calculated as shown in FIG. 29 (S68).

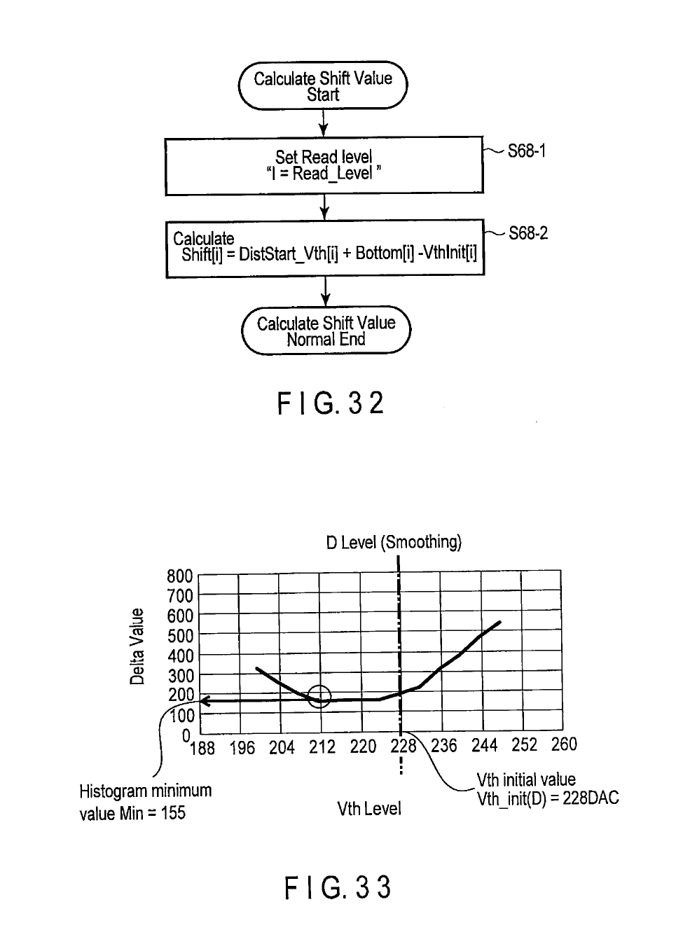

FIG. 32 is a flowchart to explain the operation of calculating a shift value. In the calculation, first Read level “i” is set in Read_Level (S68-1). After this, shift value Shift [i] is calculated on the basis of distribution read start DAC value DistStart_Vth [i], average value Bottom [i], and VthInit [i] using equation (7) (S68-2):

Shift[i]=DistStart_Vth[i]+Bottom[i]−VthInit[i] (7)

As described above, a “delta” can be obtained by subtracting “the initial value of Vth” from “Vth at the bottom of the distribution.” If no correction is needed, the “delta” is the “shift value.”

If necessary, the “delta” may be corrected to obtain the “shift value.” The simplest correction method is to add a correction value Comp(Level) previously determined for each level to the shift value obtained in FIG. 32 as expressed by equation (8):

Shift[i]=DistStart_Vth[i]+Bottom[i]−Vth_init[i]+Comp[i] (8)

The shift value is obtained as described above. Thereafter, Read level “i” is updated and the above operations are repeated until maximum value “M” of the Read level has been reached, thereby obtaining a shift value for each Read level (S69 to S63).

Here, the optimum value of Vth will be calculated using a general method and the first embodiment on the basis of data read from an actual NAND flash memory when there has been a fluctuation in distribution reading.

FIGS. 33, 34, and 35 show examples of calculating the optimum value of Vth at D level from data read from an actual NAND flash memory by a general method.

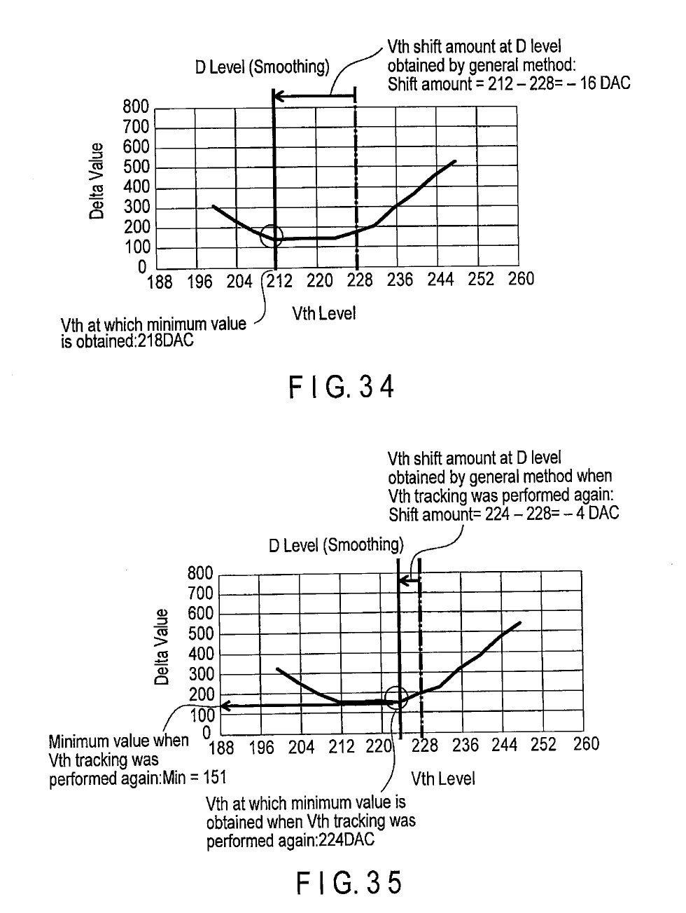

In the general method, the minimum value of a histogram obtained by calculating a five-point weighted average of difference data on the number of “1”s counted in distribution reading is searched for and Vth at which difference data takes the minimum value is found as shown in FIG. 33. In the example of FIG. 33, when Vth=212DAC, difference data takes a minimum value of “155.” Therefore, the optimum value of Vth found by the general method is 212DAC as shown in FIG. 34. A shift value at a Vth boundary for a Vth initial value of 228DAC at D level is 16DAC.

As in FIG. 28, an example of the number of “1”s included in data with Vth=224DAC decreasing by “15” due to the fluctuation of distribution reading is shown in FIG. 35.

In the example of FIG. 35, difference data takes a minimum value of 151 when Vth=224DAC. Therefore, the optimum value of Vth obtained by the general method is 224DAC and a shift value at the Vth boundary for a Vth initial value of 228DAC at D level is −4DAC.

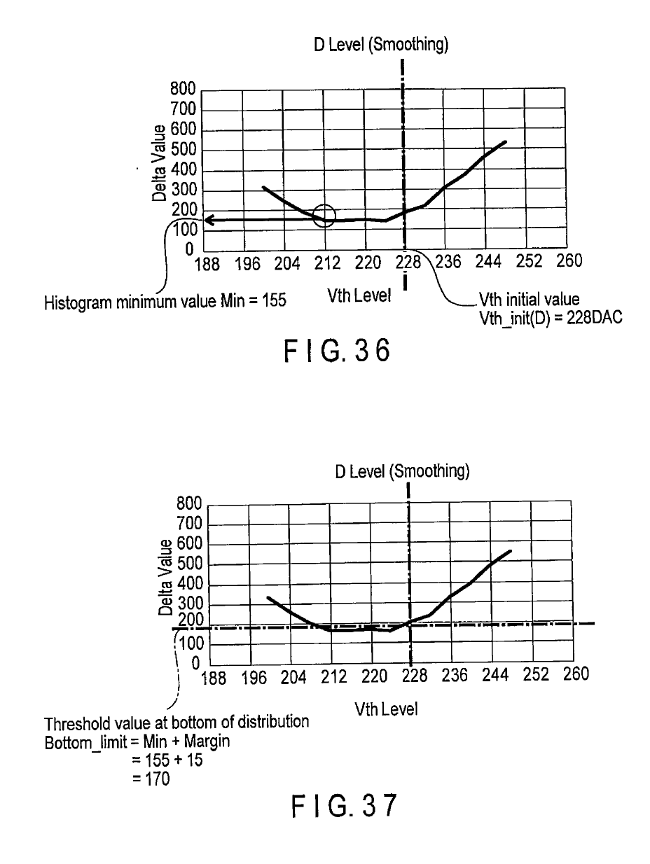

FIGS. 36, 37, and 38 show cases where the method of the first embodiment has been applied to the same examples as in FIGS. 33 and 34.

As shown in FIG. 36, in the first embodiment, the minimum value of a histogram obtained by calculating a five-point weighted average of difference data on the number of “1”s counted in distribution reading is searched for, but Vth that takes the minimum value is not calculated. In the example, when Vth=212DAC, the difference data takes a minimum value of 155.

Next, as shown in FIG. 37, a predetermined margin of 15 is added to the found minimum value, finding a threshold value for searching for “the bottom of a distribution”:

$$\begin{matrix}Threshold value = minimum value + margin \\ = 155 + 15 \\ = 170 bit\end{matrix}$$

Next, both ends of Vth at which the weighted average histogram takes values smaller than the threshold value are found. In the example, at 212DAC, 216DAC, 220DAC, and 224DAC, the histogram takes values smaller than the threshold value. Specifically, the left end of a region where the histogram takes values smaller than the threshold value is at 212DAC and the right end is at 224DAC. As seen from equation (9), the optimum value of Vth is found by calculating the average value of the DAC value at the left end of the region and the DAC value at the right end:

$$Optimum value = ( the value at the left end of the region + the value at the right end of the region ) / 2 = ( 212 + 224 ) / 2 = 218 DAC \qquad ( 9 )$$

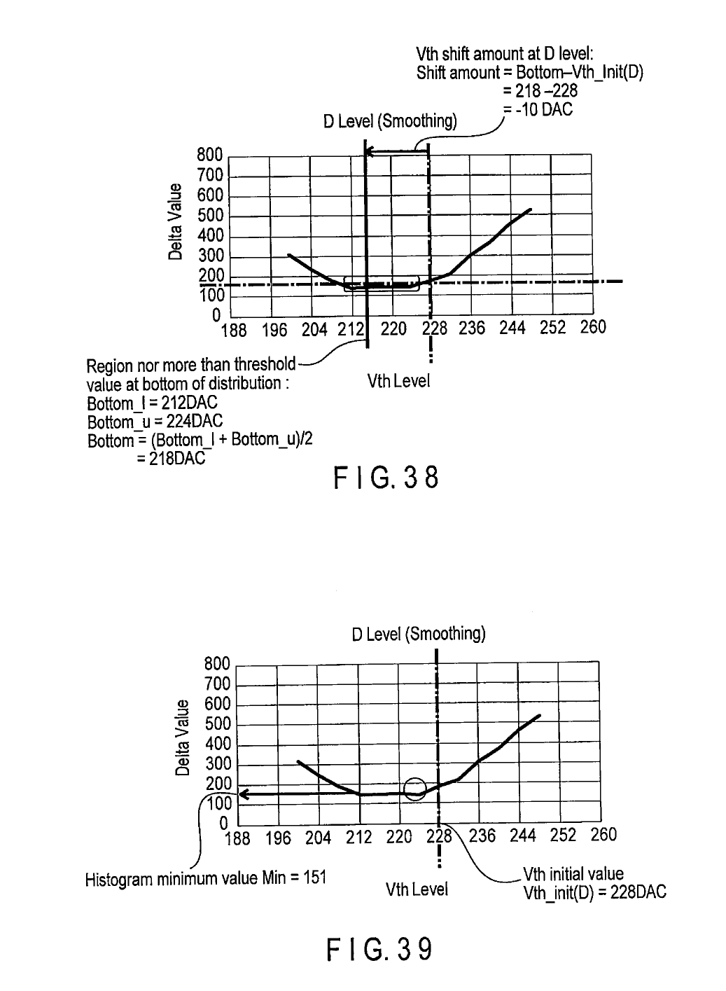

Therefore, as shown in FIG. 38, the optimum value of Vth obtained in the first embodiment is 218DAC and a shift value at the Vth boundary for a Vth initial value of 228DAC at D level is −10DAC.

FIGS. 39, 40, and 41 show cases where the method of the first embodiment has been applied to the same example as in FIG. 35.

As shown in FIG. 39, in the first embodiment, the minimum value of a histogram obtained by calculating a five-point weighted average of difference data on the number of “1”s counted in distribution reading is searched for, but Vth that takes the minimum value is not calculated. In the example, when Vth=224DAC, the difference data takes a minimum value of 151.

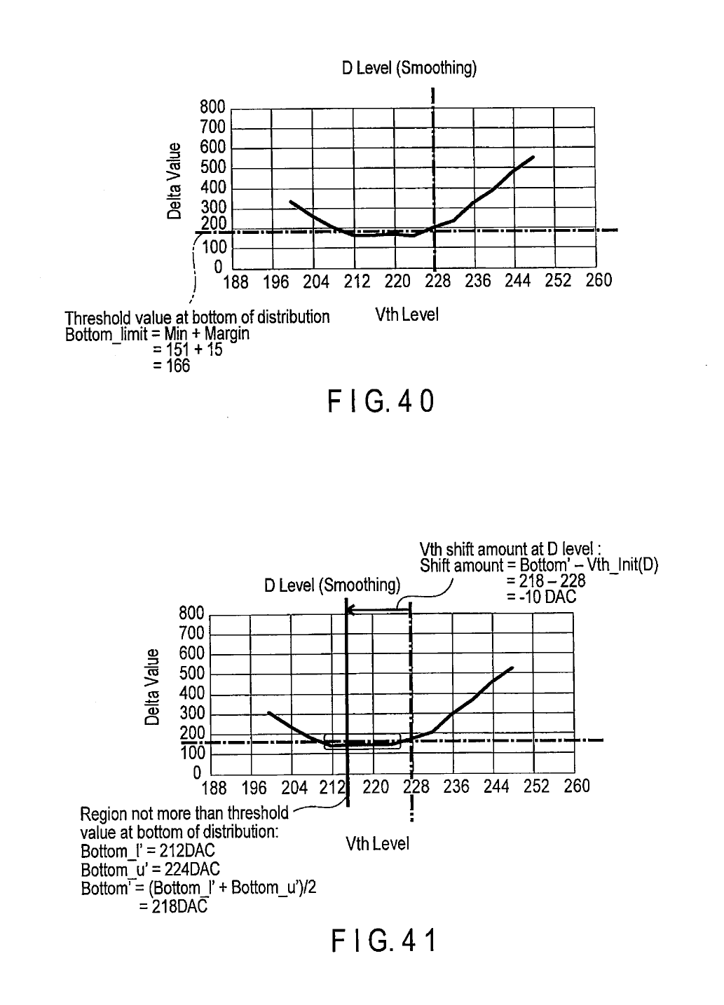

Next, as shown in FIG. 40, a predetermined margin of 15 is added to the found minimum value of 151, finding a threshold value for searching for “the bottom of a distribution” as follows:

$$\begin{matrix}Threshold value = minimum value + margin \\ = 151 + 15 \\ = 166 bit\end{matrix}$$

Next, both ends of Vth at which the weighted average histogram takes values smaller than the threshold value are found. In the example, at 212DAC, 216DAC, 220DAC, and 224DAC, the histogram takes values smaller than the threshold value “166.” Therefore, the left end of a region where the histogram takes values smaller than the threshold value is at 212DAC and the right end is at 224DAC. The optimum value of Vth is found by calculating the average value of the DAC value at the left end of the region and the DAC value at the right end as follows:

$$Optimum value = ( the value at the left end of the region + the value at the right end of the region ) / 2 = ( 212 + 224 ) / 2 = 218 DAC$$

The optimum value of Vth obtained in the first embodiment is 218DAC and a shift value at the Vth boundary for a Vth initial value of 228DAC at D level is −10DAC.

As shown in FIGS. 37 to 41, when the optimum value of Vth has been obtained by the first embodiment, even if the value in distribution reading has fluctuated, the effect of the fluctuation on the optimum value of Vth can be suppressed to a lower level than by the general method.

According to the first embodiment, difference data on the number of “1”s read from the NAND flash memory in distribution reading is found, a weighted average of the difference data is calculated for smoothing, the minimum value of the smoothed histogram is obtained, a margin is added to the minimum value to obtain a threshold value for searching for “the bottom of the distribution,” a range of Vth where the histogram takes values smaller than the threshold value is found, the values of Vth at both ends of the Vth range are found, and the average value of the Vth values at both ends is calculated, thereby finding the optimum value of Vth. Therefore, the effect of a slight fluctuation in data read in each step of distribution reading on an estimated value of the optimum value of Vth can be suppressed to a low level. Therefore, since a shift value of Vth can be determined precisely, data can be read from the NAND flash memory accurately, enabling read errors to be reduced.

While in the first embodiment, a weighted average histogram has been created using data on five points in each step, the histogram may be created using data on another number of points, for example, using data on three points.

### Second Embodiment

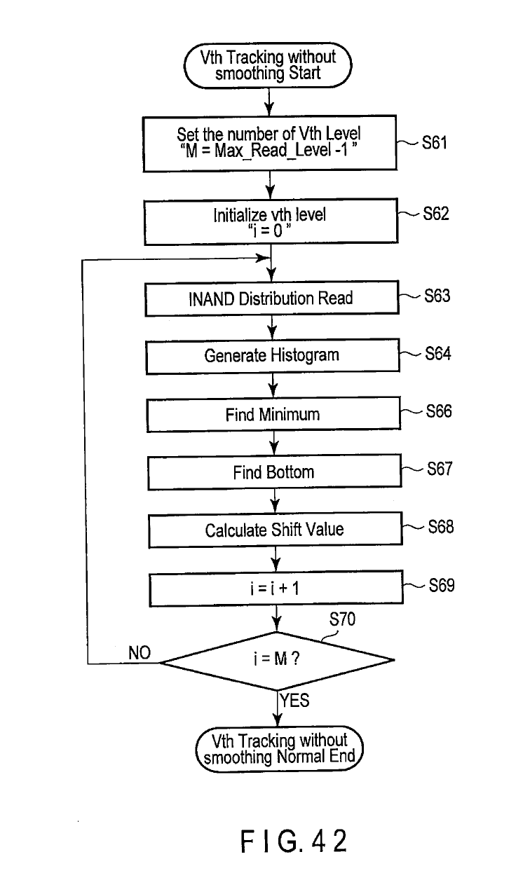

FIG. 42 is a flowchart to explain Vth tracking according to a second embodiment. In FIG. 42, the same parts as those in FIG. 29 are indicated by the same reference numerals. Only what differs from FIG. 29 will be explained.

In the first embodiment, a weighted average of difference data on the number of “1”s counted in distribution reading has been calculated and then the minimum value of the weighted average histogram has been found (FIGS. 29, S61 to S65, S66).

In contrast, in the second embodiment, a histogram of difference data is searched twice without calculating a weighted average of difference data on the number of “1”s as shown in FIG. 42 (S61 to S64, S66, S67). As in the first embodiment, in the second embodiment, there is no need to store a DAC value corresponding to Vth that takes the minimum value in searching for the minimum value.

In the second embodiment, a predetermined margin, for example, “15”, is added to the minimum value obtained in a first search (S66), thereby creating a threshold value at the bottom of the distribution. Thereafter, a second search (67) is made and a range where the histogram of difference data takes values smaller than the threshold value at the bottom of the distribution, that is, a region of the bottom of the distribution, is searched for. In the second search, a maximum value and a minimum value of Vth in the region of the bottom of the distribution are stored.

After the second search, the average value of the maximum value and minimum value of Vth in the region of the bottom of the distribution is found. The average value is added to the start DAC value in distribution reading, thereby finding the value of Vth at the bottom of the distribution and further finding a shift value (S68).

In addition, the above operations are repeated until the Read level has reached maximum value M (S69, S70 to S63).

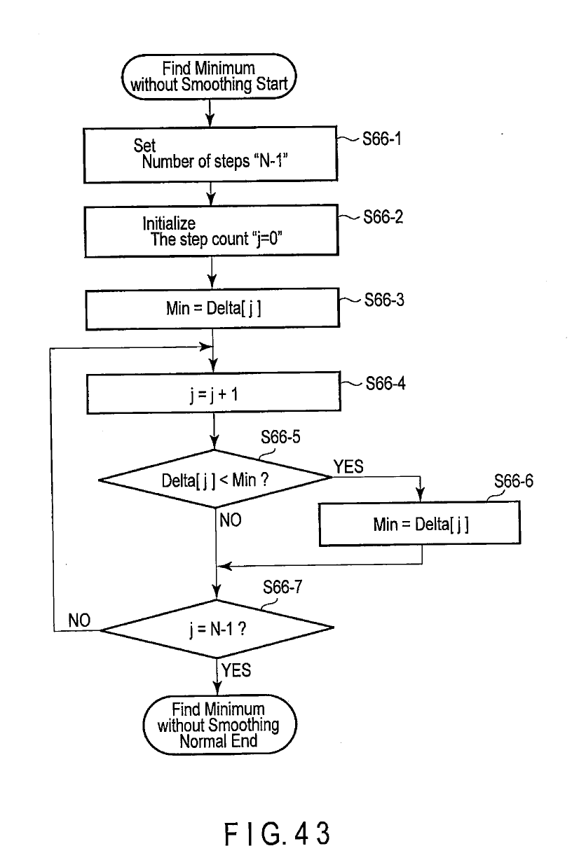

FIG. 43 is a flowchart to concretely explain a first search, or the operation of searching for the minimum value (S66). FIG. 43 and FIG. 30 differ from each other as follows: in FIG. 30, a search object is a histogram obtained by smoothing difference data, whereas, in FIG. 43, a search object is difference data itself.

Specifically, in FIG. 43, the number of steps is initialized to “N−1” (S66-1), step count “i” is initialized to “0” (S66-2), and minimum value Min is initialized to Delta(i) (S66-3). In this state, step count “i” is updated and the minimum value of difference data is searched for (S66-4 to S66-7). The operation of searching for the minimum value is the same as in FIG. 30 and therefore a detailed explanation will be omitted.

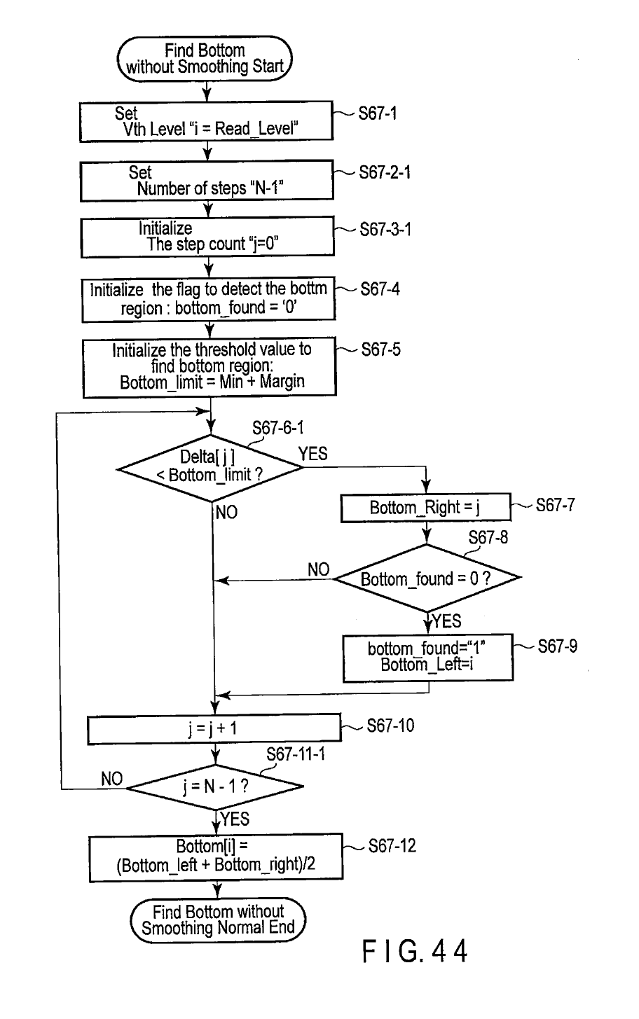

FIG. 44 is a flowchart to explain a second search (S67) shown in FIG. 42, that is, an example of the operation of adding a margin to minimum value Min obtained in the first search to generate a threshold value at the bottom of the distribution and searching for a range of Vth that takes values smaller than the threshold value is searched for.

FIG. 44 differs from FIG. 31 in the setting of the number of steps (S67-2-1), the initial setting of the step count (S67-3-1), and the process of determining a minimum value on the basis of difference data (S67-6-1), and is the same as FIG. 31 in the remaining part. Therefore, the same parts as those in FIG. 31 are indicated by the same reference numerals and a concrete explanation will be omitted.

By the operation of FIG. 44, a range of Vth that takes values smaller than the threshold value set on the basis of the minimum value based on difference data is determined.

Thereafter, as shown in FIG. 32, a difference is obtained by subtracting the initial value of Vth from the Vth at the bottom of the distribution using equation (10) and the difference is determined to be a shift value:

Shift[i]=DistStart_Vth[i]+Bottom[i]−VthInit[i] (10)

If correction is necessary, preset correction value Comp(Level) is added, giving a shift value.

Like the first embodiment, the second embodiment can suppress the effect of slight variations in the data read in each step of distribution reading on an estimated value of the optimum value of Vth.

Unlike the first embodiment, the second embodiment need not calculate a weighted average of difference data, with the result that the number of steps of a histogram obtained by performing distribution reading in the same number of steps as in the first embodiment becomes larger than in the first embodiment.

For example, when distribution reading is performed 25 times to obtain the optimum value of Vth at D level, a histogram has 24 points of effective data as a result of the operation of obtaining difference data to create a histogram in the second embodiment. In contrast, in the first embodiment, after the operation of obtaining difference data, effective data items decrease by four points as a result of the operation of calculating a five-point weighted average. Therefore, the histogram has 20 points of effective data.

As described above, the second embodiment need not calculate a weighted average of difference data and therefore can make the processing time shorter than the first embodiment. However, the second embodiment is more liable to be affected by the fluctuation of a histogram than the first embodiment.

### Third Embodiment

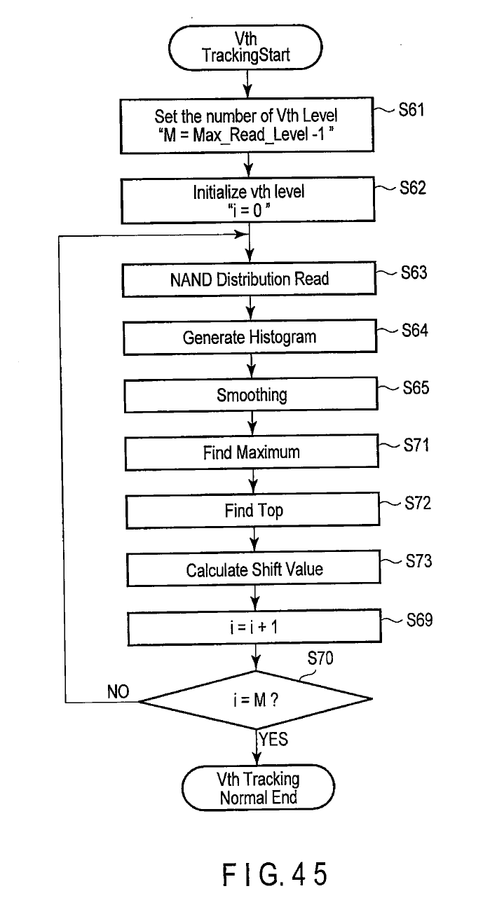

FIG. 45 is a flowchart to explain Vth tracking according to a third embodiment. The first and second embodiments have searched for the bottom of a Vth distribution. In contrast, the third embodiment searches for the top (projecting part) of a Vth distribution. Specifically, in a first search, a local maximum value, not a local minimum value, of a Vth distribution is obtained. On the basis of the obtained maximum value of the Vth distribution, a “threshold value” is determined. In a second search, instead of the bottom of the Vth distribution, the top of the Vth distribution that takes a value larger than the “threshold value” is searched for.

FIG. 45 is the same as the first embodiment shown in FIG. 29, except for a first search operation (S71), a second search operation (S72), and the operation of calculating a shift value (S73). Therefore, only the first search operation (S71), second search operation (S72), and the operation of calculating a shift value (S73) will be explained.

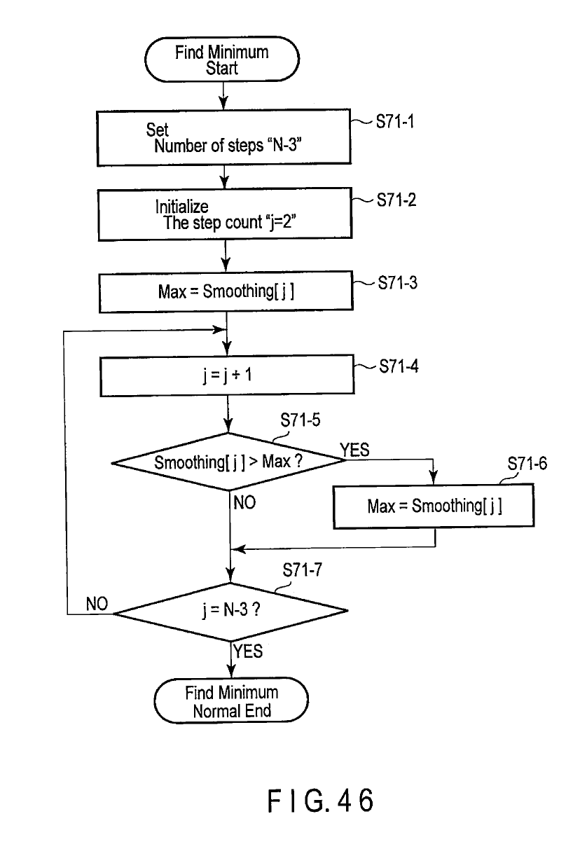

FIG. 46 is a flowchart to explain the first search operation (S71). In the first search operation, first, the number of steps is set to “N−3” (S71-1) and the step count is initialized to “i=2” (S71-2). In this state, the value of the smoothed histogram is set as maximum Max (S71-3). Thereafter, step count “i” is incremented (S71-4) and it is determined whether the value of the smoothed histogram is larger than maximum value Max (S71-5). The result of the determination has shown that if the value of the smoothed histogram is larger than maximum value Max, maximum value Max is updated (S71-6). The above operations are repeated until step count “i” has reached the number of steps “N−3” (S71-7 to S71-4).

As described above, in the first search, one maximum value is searched for. As in the first embodiment, there is no need to store a DAC value corresponding to Vth that takes the maximum value in the first search.

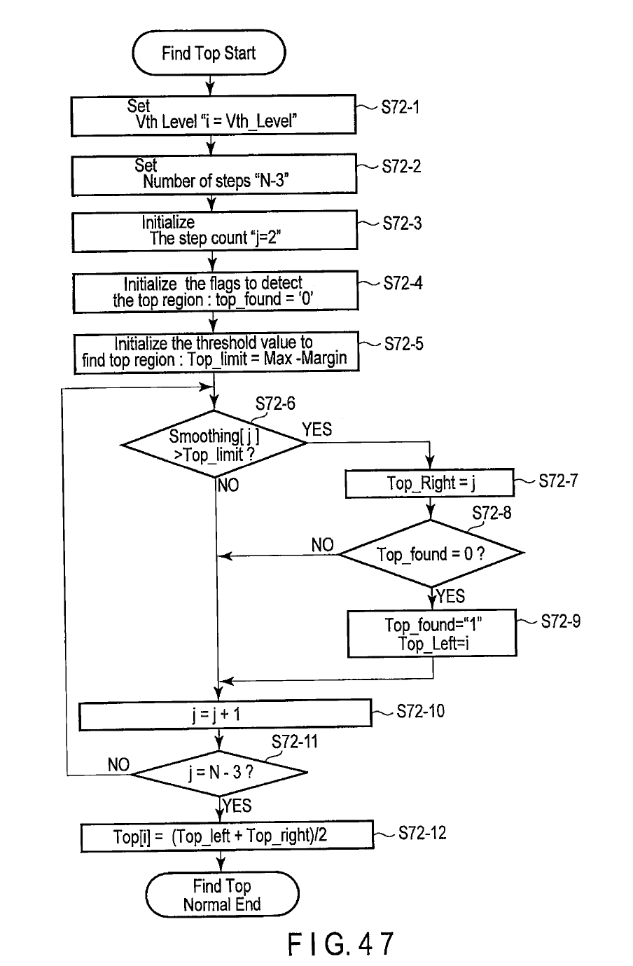

FIG. 47 is a flowchart to explain the second search operation (S72). In the second search operation, one maximum value and one minimum value of Vth are detected as a region of the top of the distribution. Specifically, in the second search operation, a margin is subtracted from the maximum value obtained in the first search operation (S71), thereby giving a threshold value at the top of the distribution. Then, a range of Vth that takes values larger than the threshold value is searched for.

Specifically, in FIG. 47, first, the Read level is initialized to “i=Read level” (S72-1) and the number of steps is set to “N−3” (S72-2). Then, the step count is initialized to “i=2” (S72-3) and flag Top_found indicating that the top region has been found is initialized to “0” (S72-4). Thereafter, a margin is subtracted from the maximum value obtained in the first search operation (S71) and threshold value Top_limit is set (S72-5).

In this state, it is determined whether the value of the smoothed histogram is larger than threshold value Top_limit (S72-6). The result of the determination has shown that if the value of the histogram is larger than threshold value Top_limit, Top_Right is set to “i” (S72-7). Thereafter, it is determined whether flag Top_found is “0” (S72-8). In this case, since flag Top_found is “0,” flag Top_found is set to “1” and Top_Left is set to “i” (S72-9). That is, the minimum value of Vth in the region of the top of the distribution is set in Top_Left.

Thereafter, step count “i” is incremented and the above operations are repeated until step count “i” has reached “N−3” (S72-10, S72-11 to S72-6). In this way, the maximum value of Vth in the region of the top of the distribution is set in Top_Right.

In step S71-11, if it has been determined that step count “i” has reached “N−3,” the average value of the maximum value and minimum value of Vth in the region of the top of the distribution is calculated using equation (11):

Top[i]=(Top_Left+Top_Right)/2 (11)

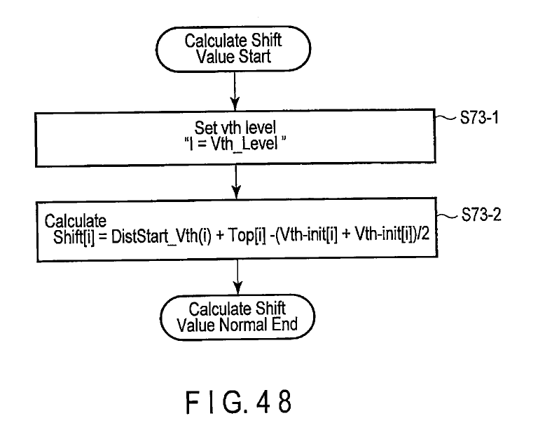

FIG. 48 is a flowchart to explain the operation of calculating a shift value (S73). A shift value is obtained by subtracting the average value of the initial values of Vth at both ends of the top from the Vth at the top of the distribution. Specifically, the Vth level is set to “i=Vth_Level” (S73-1) and a shift value is calculated using equation (12) (S73-2):

Shift[i]=DistStart_Vth[i]+Top[i]−(Vth_init[i−1]+Vth_init[i])/2 (12)

If necessary, correction value Comp(Level) previously determined for each level may be added to the shift value obtained using equation (12).

According to the third embodiment, a shift value of the maximum value of the histogram can be found. A shift value of the minimum value can be estimated by adding or subtracting a correction value to or from the shift value of the maximum value. On the basis of the shift value, the read voltage of the NAND flash memory 20 is controlled, which enables the error rate of data read from the NAND flash memory 20 to be decreased even in the third embodiment.

The third embodiment is not limited to the above operations and may search for the maximum value on the basis of a histogram of difference data instead of calculating a weighted average of difference data as in the second embodiment.

### Fourth Embodiment

The first to third embodiments have searched for the bottom or top of a distribution. In contrast, a fourth embodiment also checks whether the top of a distribution is present within a search range in a first search operation when searching for the bottom of the distribution. If the top of the distribution is present within the search range, the minimum value is searched for in front of and behind the top of the distribution and a plurality of threshold values at the bottom of the distribution are set in a second search operation. That is, like the third embodiment, the fourth embodiment performs a first search operation for determining minimum value Minimum lower (hereinafter, referred to as min_l) on the left side of the top of the distribution (on the side where the Vth level is lower than the top of the distribution) and minimum value Minimum_upper (hereinafter, referred to as min_u) on the right side of the top of the distribution (on the side where the Vth level is higher than the top of the distribution) and a second search operation for determining threshold value bottom_l_limit on the left side of the bottom of the distribution and threshold value bottom_u_limit on the right side of the bottom of the distribution.

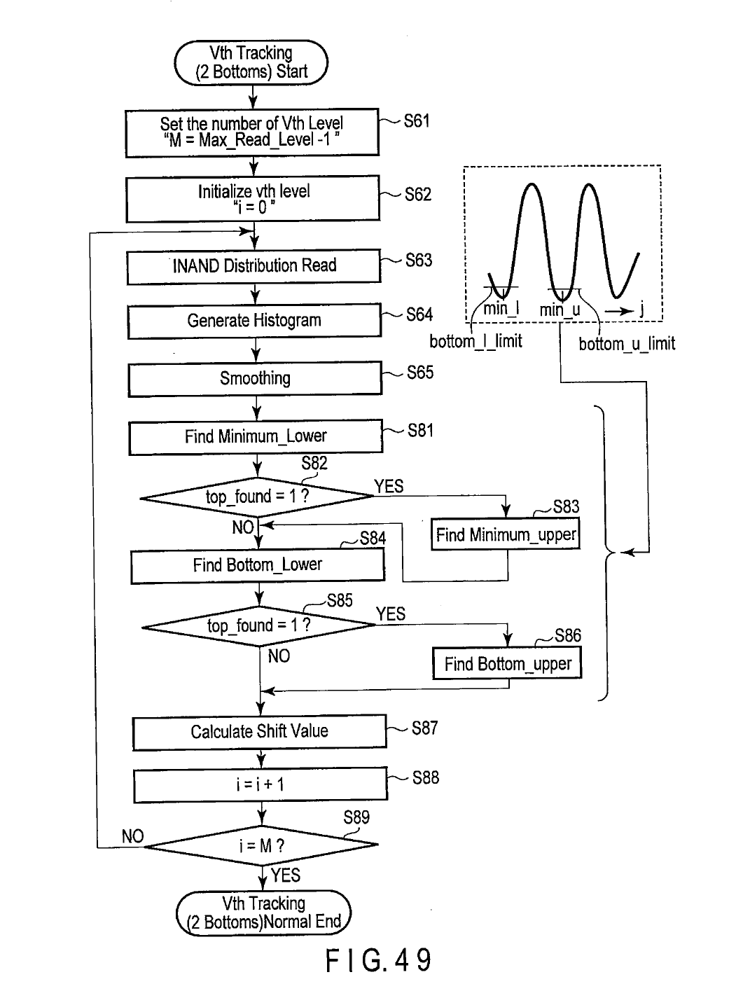

FIG. 49 is a flowchart to explain a rough operation of Vth tracking according to the fourth embodiment.

The operation of the fourth embodiment will be explained roughly with reference to FIG. 49. In FIG. 49, the operation in step S61 up to smoothing in step S65 are the same as in the third embodiment and therefore an explanation of them will be omitted.

The first half of the first search operation is performed in step S81, searching for minimum value min_l on the left side of the top of the distribution. When the top has been detected in the middle of the search, flag top_found, described later, is set to “1.” After the first half of the first search operation has been completed, it is determined whether flag top_found is “1” (S82). If flag top_found is “1,” meaning that the top has been detected, the second half of the first search operation is performed, searching for minimum min_u on the right side of the top of the distribution (S83).

After minimum min_l on the left side of the top of the distribution and minimum min_u on the right side of the top of the distribution have been detected as described above, the first half of the second search is performed (S84). In the first half of the second search operation, a margin is added to minimum min_l on the left side of the top of the distribution to set threshold value bottom_l_limit at the bottom of the distribution by the same operations as in the first embodiment. Then, the minimum value and maximum value of Vth in a region of the bottom of the distribution determined by the threshold value bottom_l_limit are searched for.

Thereafter, it is determined whether flag top_found is “1” (S85). If whether flag top_found is “1,” the second half of the second search operation is performed (S86). In the second half of the second search operation, a margin is added to minimum min_u on the right side of the top of the distribution to set threshold value bottom_u_limit at the bottom of the distribution by the same operations as in the first half of the second search operation. Then, the minimum value and maximum value of Vth in a region of the bottom of the distribution determined by the threshold value bottom_u_limit are searched for.

The central value between the minimum value and maximum value of Vth in the region of the bottom on the left side of the top of distribution obtained in this way and the central value between the minimum value and maximum value of Vth in the region of the bottom on the right side of the top of distribution are calculated to find a Vth level at the bottom with the lower Vth and a Vth level at the bottom with the higher Vth level (S87).

Such operations are repeated, while Read level “i” is being updated (S88), until Read level “Max_Read_Level−1” has been reached (S89 to S63).

To execute the above operations, the fourth embodiment uses two threshold values and three or four flags in order to search for the top of the distribution.

(1) As for first threshold value top_high_limit, when the value of a histogram becomes larger than this value, the region of the top of the distribution is regarded as having been detected. For example, suppose, in a histogram not subjected to a smoothing process, top_high_limit is at, for example, 150 bit and, in a histogram subjected to a smoothing process, top_high_limit is at, for example, 300 bit.

(2) As for second threshold value top_low_limit, when the value of a histogram becomes smaller than this value, the region of the bottom of the distribution is regarded as having been detected. For example, suppose, in a histogram not subjected to a smoothing process, top_low_limit is at, for example, 100 bit and, in a histogram subjected to a smoothing process, top_low_limit is at, for example, 200 bit.

(3) After flag bottom_l_found has been initialized to “0,” the histogram is searched, starting at lower Vth. When the bottom of the distribution has been found, flag bottom_l_found is set to “1.” That is, the values of the histogram are checked, starting at lower Vth. When a value of the histogram becomes smaller than top_low_limit, bottom_l_found is set to “1.”

(4) After flag top_found has been initialized to “0,” the histogram is searched, starting at lower Vth. With flag bottom_l_found being “1,” when the top of the distribution has been found, flag top_found is set to “1.” That is, the values of the histogram are searched, starting at lower Vth. With flag bottom_l_found being “1,” when a value of the histogram becomes larger than top_high_limit, flag top_found is set to “1.”

(5) After flag bottom_u_found has been initialized to “0,” the histogram is searched, starting at lower Vth. With top_found being “1,” when the bottom of the distribution has been found, flag bottom_u_found is set to “1.” That is, the values of the histogram are searched, starting at lower Vth. With top_found being “1,” when a value of the histogram becomes smaller than top_low_limit, flag bottom_u_found is set to “1.”

(6) After flag search_end has been initialized to “0,” the histogram is searched, starting at lower Vth. With bottom_l_found being “1,” when the top of the distribution has been found, flag search_end is set to “1.” That is, the values of the histogram are searched, starting at lower Vth. With bottom_l_found being “1,” when a value of the histogram becomes larger than top_high_limit, flag search_end is set to “1.”

Flag search_end is optional and may not be used.

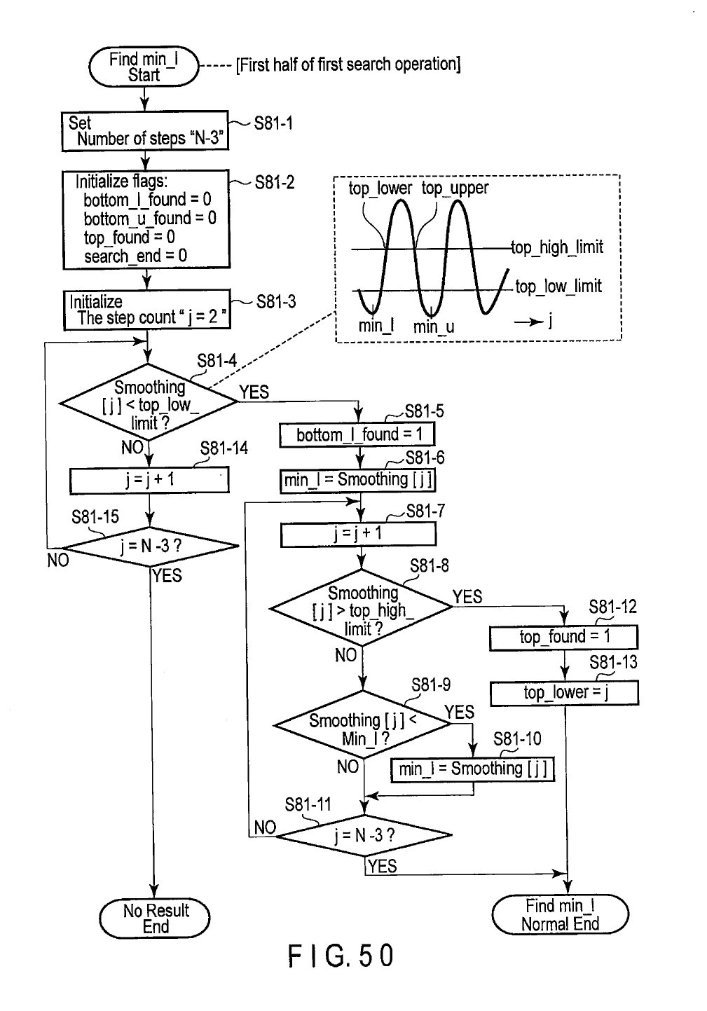

Next, the first and second search operations will be explained concretely with reference to FIGS. 50 to 53.

(First Half of the First Search Operation)

FIG. 50 is a flowchart to explain the first half of the first search (top search) operation. In a rough operation of the first search, minimum value min_l on the left side of the top of the distribution is updated until flag top_found has reached “1,” thereby finding minimum value min_l in an interval where flag top_found is “0.” When flag top_found has reached “1,” minimum value min_l is determined.

Specifically, in the first half of the first search operation, first, the number of steps is set to “N−3” (S81-1) and flag bottom_l_found, bottom_u_found, top_found, and search_end are reset to “0” (S81-2). Then, the step count is set to “j=2” (S81-3) and the histogram is searched, starting at lower Vth. Specifically, it is determined whether value Smoothing [j] of the smoothed histogram is smaller than the second threshold value top_low_limit (S81-4). If the result has shown that value Smoothing [j] of the histogram is smaller than the second threshold value top_low_limit, flag bottom_l_found is set to “1” (S81-5).

That is, since the bottom has been detected, value Smoothing [j] of the histogram is set to minimum value min_l (S81-6), step count “j” is incremented (S81-7), and it is determined whether value Smoothing [j] of the histogram is larger than the first threshold value top_high_limit (S81-8). If the result has shown that value Smoothing [j] of the histogram is smaller than the first threshold value top_high_limit, it is determined whether value Smoothing [j] of the histogram is smaller than minimum value min_l (S81-9). If the result of the determination has shown value Smoothing [j] of the histogram is smaller than minimum value min_l, minimum value Min is updated (S81-10). Thereafter, it is determined whether step count “j” has reached the number of steps “N−3” (S81-11). If step count “j” has not reached the number of steps “N−3,” step count “j” is incremented (S81-7) and the above operations are repeated.

By the above operations, in step (S81-3), if it has been determined that value Smoothing [j] of the histogram is larger than the first threshold value top_high_limit, flag top_found is set to “1” (S81-12) and step count “j” is set to minimum value top_lower on the left side of the top region (S81-13). With flag top_found being set to “1,” minimum value min_l on the left side of the top of the distribution is determined.

If the result of the determination in step (S81-4) has shown that value Smoothing [j] of the histogram is larger than the second threshold value top_low_limit, step count “j” is incremented (S81-14) and the determination in step (S81-4) is repeated. If value Smoothing [j] of the histogram does not become less than top_low_limit until step count “j” has reached the number of steps “N−3,” starting at step 2 (S81-15), a search result cannot be obtained.

(Second Half of the First Search Operation)

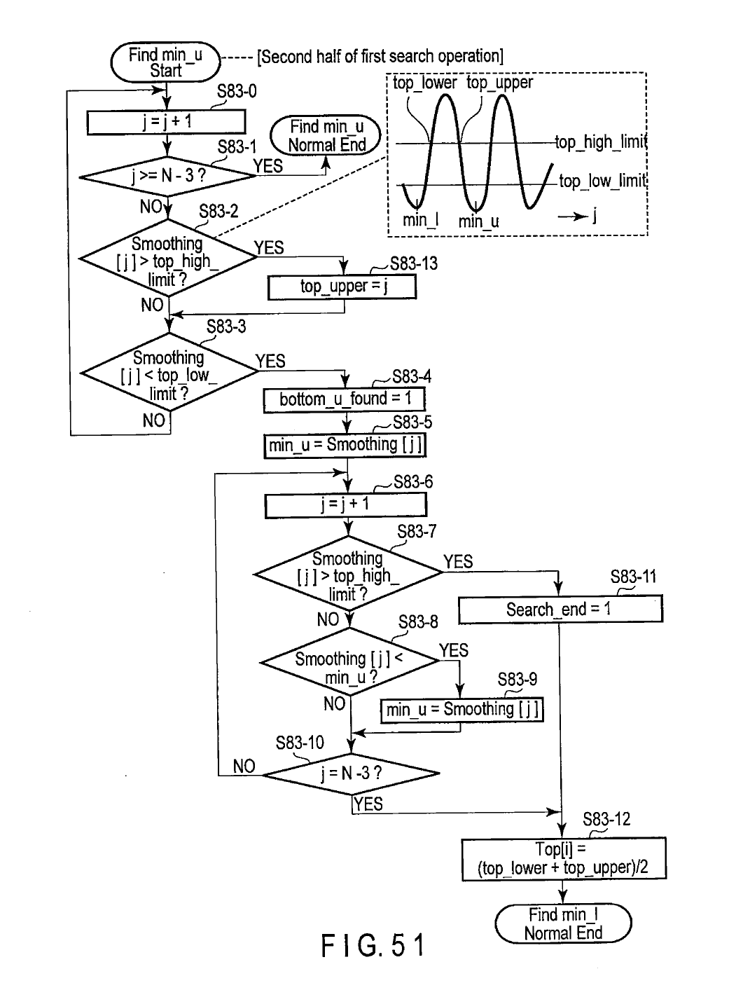

FIG. 51 is a flowchart to explain the second half of the first search operation.

As described above, when flag top_found is set to “1,” minimum value min_l on the left side of the top is not updated. Therefore, when flag top_found has been set to “1,” minimum value min_l on the left side of the top is determined. In this state, neither minimum value min_l on the left side of the top nor minimum value min_u on the right side of the top is updated until the value of the histogram has become smaller than the second threshold value top_low_limit.

With flag top_found being “1,” step count “j” is updated (S83-0) and, if j is smaller than N−3 (S83-1), a search is further made. If value Smoothing [j] of the histogram is larger than the first threshold value top_high_limit (S83-2), top_upper is set to j (S83-13). If value Smoothing [j] of the histogram becomes smaller than the second threshold value top_low_limit (S83-3), flag bottom_u_found is set to “1” (S83-4). In addition, the value of the histogram is set to minimum value min_u on the right side of the top (S83-5).

In this state, step count “j” is updated (S83-6) and minimum value min_u on the right side of the top is searched for, while minimum value min_u on the right side of the top is being updated, until step count “j” has reached “N−3” (S83-7, S83-8, S83-9, S83-10).

Since flag top_found has been set to “1,” minimum value min_l on the left side of the top is not updated.

When step count “j” has reached “N−3,” the average value of the maximum value and minimum value of Vth in the region of the top of the distribution is calculated using equation (13) (S83-12):

Top[j]=(top_lower+top_upper)/2 (13)

In addition, when flag search_end is used, if, in step (S83-7), the value of the histogram becomes larger than the first threshold value top_high_limit with flag bottom_u_found being “1,” flag search_end is set to “1” (S83-11) and the average value of the maximum value and minimum value of Vth in the region of the top of the distribution is calculated (S83-12).

In step (S83-2), if the value of the histogram is smaller than the first threshold value top_high_limit and the search operation has ended with flag bottom_u_found being “0” (S38-1), this means that the entire top of the distribution is not included in the search range. In this case, since only one bottom of the distribution is included in the search range, minimum value min_l on the left side of the top is treated as minimum value min in the third embodiment and a second search is made, thereby finding the position of the bottom of one distribution.

In addition, when optional flag search_end is used, if the search operation has ended with flag search_end being “1,” the entire top of the distribution is included in the search range, the bottoms of two distributions are found on both sides of the top, and it is seen that the entire bottom of the distribution on the right side of the top of the distribution (a region where Vth is higher than the top of the distribution) is included in the search range.

(First Half of the Second Search Operation)

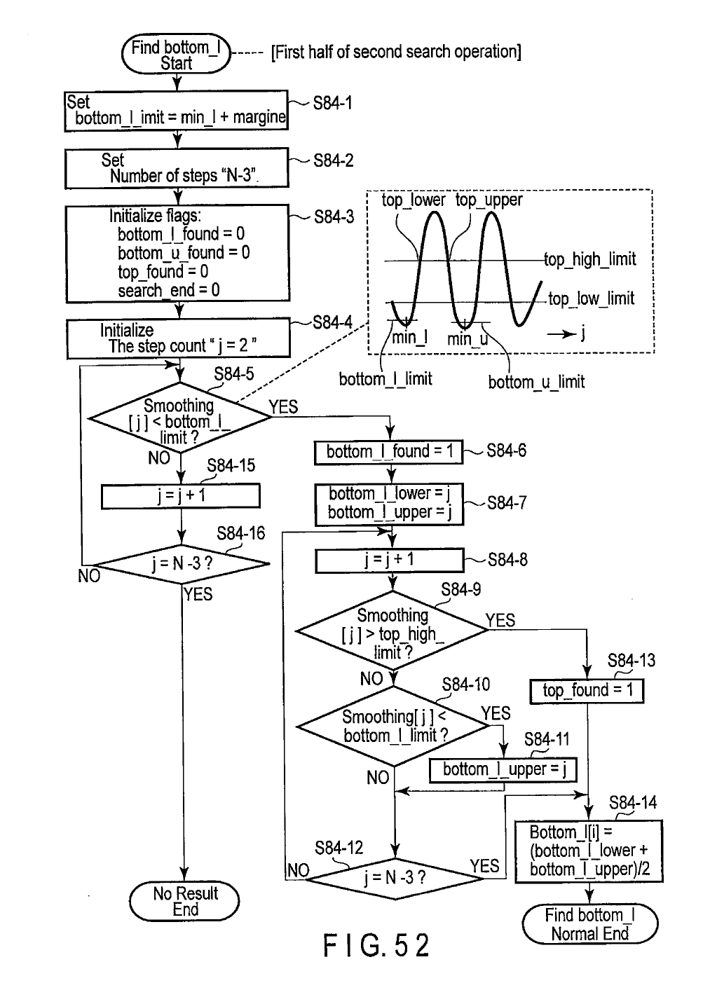

FIG. 52 is a flowchart to explain the first half of the second search operation.

When a search has ended with flag bottom_u_found being “1” in a first search operation, this means that the entire “top of distribution” is included in the search range and two candidates for the “bottom of distribution” are present. In this case, a second search operation is performed as described below, thereby detecting the bottoms of two distributions.

First, as in the first embodiment, a predetermined margin, for example, 15 bit, is added to minimum value min_l, thereby finding threshold value bottom_l_limit as shown by equation (14) (S84-1):

bottom_{—}l_limit=min_{—}l+15 (14)

Then, the number of steps is set to “N−3” (S84-2), flags bottom_l_found, bottom_u_found, top_found, and search_end are reset to “0” (S84-3), and the step count is set to “j=2” (S84-4).

In this state, the values of the histogram are compared with threshold value bottom_l_limit sequentially, starting at the minimum value of Vth in the search range, in order to determine whether the values of the histogram are smaller than threshold value bottom_l_limit (S84-5). If the comparison result has shown that the values of the histogram are smaller than threshold value bottom_l_limit, flag bottom_l_found is set to “1” (S84-6) and the value of step count “j,” that is, the value of Vth, is set in bottom_l_lower and bottom_l_upper (S84-7). After this, bottom_l_lower is not updated.

With flag top_found being “0” and flag bottom_l_found being “1,” step count “j” is updated (S84-8) and the values of the histogram are compared with threshold values top_high_limit and bottom_l_limit (S84-9, S84-10). If the comparison result has shown that the values of the histogram are smaller than threshold value top_high_limit (S84-9) and smaller than bottom_l_limit (S84-10), the value of step count “j” at that time, that is, the value of Vth, is set in bottom_l_upper (S84-11).

Thereafter, when step count “j” has reached “N−3” or when flag search_end is used, if the values of the histogram are smaller than threshold value botton_l_limit, the value of bottom_l_upper is updated until the values of the histogram have exceeded threshold value top_high_limit (S84-12, S84-8).

In step (S84-9), when the values of the histogram have exceeded threshold value top_high_limit, flag top_found is set to “1” (S84-13). At this time, it is determined that a first bottom as a whole has been detected. Thereafter, in step (S132), average value Bottom [j] of bottom_l_lower and bottom_l_upper is calculated using equation (15) as when step count “j” has reached “N−3” (S84-14):

Bottom_{—}l[j]=(bottom_{—}l_lower+bottom_{—}l_upper)/2 (15)

When the search has ended while the values of the histogram remain larger than threshold value bottom_l_limit, with flag top_found being “0” (S84-5, S85-15, S84-16), the chances are high the first bottom as a whole has not been detected.

(Second Half of the Second Search Operation)

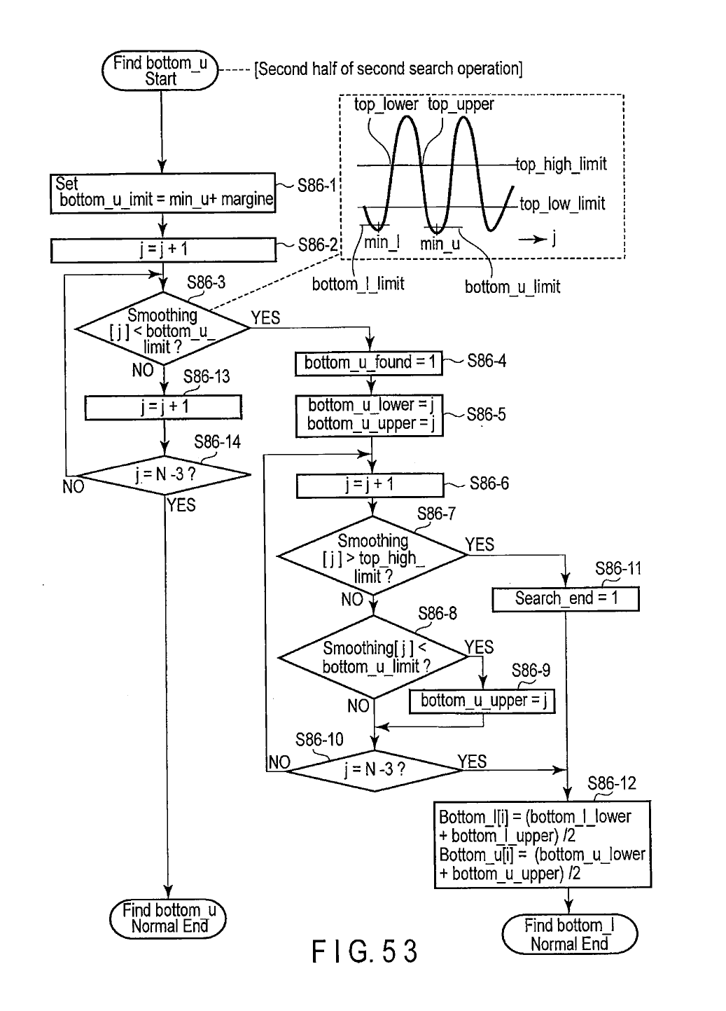

FIG. 53 is a flowchart to explain the second half of the second search operation.

As in the first half of the second search operation, a predetermined margin, for example, 15DAC, is added to minimum value min_u, thereby finding threshold value bottom_u_limit as shown by equation (16) (S86-1):

bottom_{—}u_limit=min_{—}u+15 (16)

After this, the step count is set to “j=j+1” (S86-2).

In this state, the values of the histogram are compared with threshold value bottom_u_limit sequentially, starting at the minimum value of Vth in the search range, in order to determine whether the values of the histogram are smaller than threshold value bottom_u_limit (S86-3). If the comparison result has shown that the values of the histogram are smaller than threshold value bottom_u_limit, flag bottom_u_found is set to “1” (S86-4) and the value of step count “j,” that is, the value of Vth, is set in bottom_u_lower and bottom_u_upper (S86-5). After this, bottom_u_lower is not updated.

Then, step count “j” is updated (S86-6) and the values of the histogram are compared with threshold values top_high_limit and bottom_u_limit (S86-7, S86-8). If the comparison result has shown that the values of the histogram are smaller than threshold value top_high_limit (S86-7) and smaller than bottom_u_limit (S86-8), the value of step count “j” at that time, that is, the value of Vth, is set in bottom_u_upper (S86-9).

Thereafter, when step count “j” has reached “N−3” or when flag search_end is used, if the values of the histogram are smaller than threshold value botton_u_limit, bottom_u_upper is updated until the values of the histogram have exceeded threshold value top_high_limit (S86-10, S86-6).

In step (S86-7), when the values of the histogram have exceeded top_high_limit, flag Search_end is set to “1” (S86-11). When optional flag search_end is used, none of minimum values bottom_l_lower, bottom_l_upper, bottom_u_lower, and bottom_u_upper are updated after flag search_end has been set to “1.”

In step (S86-10), when step count “j” has reached “N−3” or when flag Search_end has been set to “1,” the positions of two bottoms, that is, Vth level Bottom_l [j] at a bottom with lower Vth and Vth level Bottom_u [j] at a bottom with higher Vth, are calculated from minimum values bottom_l_lower, bottom_l_upper, bottom_u_lower, and botton_u_upper obtained as described above using equation (17) (S86-12):

Bottom_{—}l[i]=(bottom_{—}l_lower+bottom_{—}l_upper)/2

Bottom_{—}u[i]=(bottom_{—}u_lower+bottom_{—}u_upper)/2 (17)

The position of each of the bottoms is effective if flag bottom_l_found is at “1”, Bottom_l[i] is effective, and if flag bottom_u_found is at “1”, Bottom_u[i] is effective.

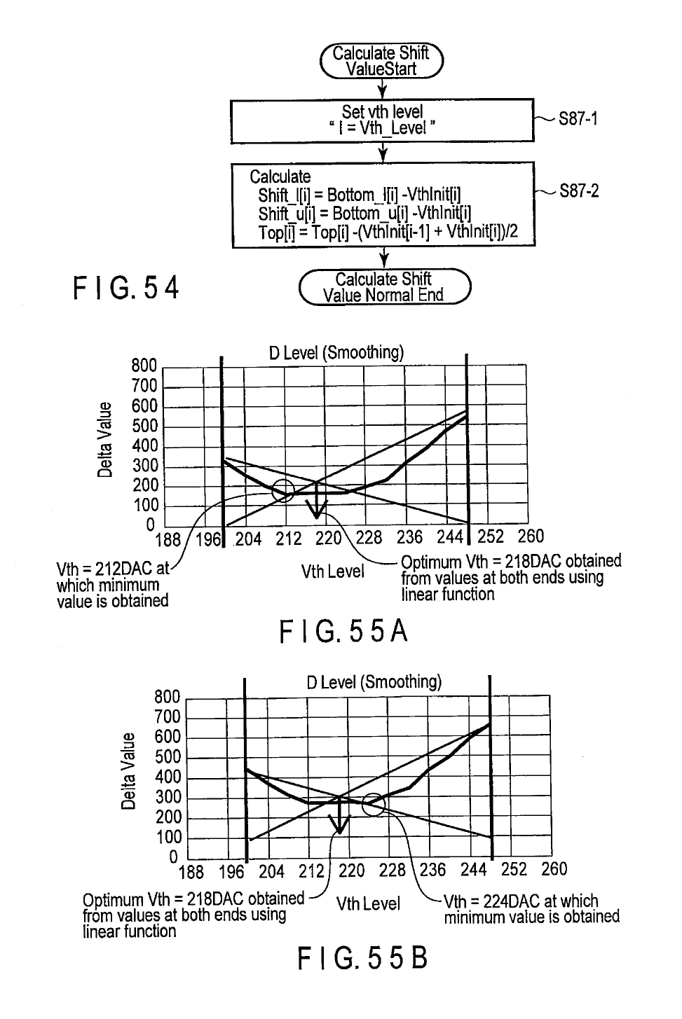

After this, as shown in FIG. 54, shift values from the initial Vth levels (VthInit) at two bottoms are calculated from positions Bottom_l [i] and Bottom_u [i] of the two bottoms using equations (18):

Shift_{—}l[i]=Bottom_{—}l[i]−VthInit[i]

Shift_{—}u[i]=Bottom_{—}u[i]−VthInit[i] (18)

While in the fourth embodiment, a search has been made on the assumption that there are a plurality of bottoms in the search range of the distribution, a search may be made on the assumption that there are a plurality of tops in the search range of the distribution, and a search may be made to the assumption that there are a plurality of bottoms and tops in the search range of the distribution.

The fourth embodiment also searches for a top in the search range when searching for a bottom of the distribution. Therefore, when a search is made on the assumption that only one bottom or top of the distribution is present in the search range, if the top of the distribution has been detected while the bottom of the distribution reading is being searched for or if the bottom of the distribution has been detected while the top of the distribution reading is being searched for, it might be determined erroneously that the top is in the position of the bottom of the distribution or that the bottom is in the position of the top. In the fourth embodiment, however, such an erroneous operation can be prevented.

In addition, since the fourth embodiment makes a search on the assumption that there are a plurality of bottoms in the search range of the distribution, even if the shift amount of the distribution is larger than expected, the chances are high the bottom of the correct distribution is included, enabling the reliability of estimation of the shift amount to be increased.

### Fifth Embodiment

A fifth embodiment is such that it is also determined whether the top of a distribution is present in a search range when the bottom of the distribution is found.

Specifically, in the fifth embodiment, when the top of the distribution has been detected in the search range, difference information on a Vth level found from the position of the top of the distribution and the original Vth distribution is used. For example, when the top of the distribution has been found in searching for F level, if the top is in a position where the Vth level is lower than F level, it is estimated that the bottom is in a direction in which the Vth level is lower than the top, that is, in a position expressed by:

(the position of the top)−(the difference between F level and E level of the original Vth)

and/or that the bottom is in a direction in which the Vth level is higher than the top, that is, in a position expressed by:

(the position of the top)+(the difference between G level and F level of the original Vth).

Specifically, Vth in step (S81-3) of the first half of the first search operation shown in FIG. 50 and Vth in step (S81-9) of the second half of the first search operation shown in FIG. 51 are recorded in minimum values top_lower and top_upper, respectively. From the average value of these, the position of the top can be found as expressed by the following equation:

The position of the top

=(top_lower+top_upper)/2

The position of the top is effective if flag bottom_u_found is “1” when the search operation has ended.

The operations of the fifth embodiment are the same as those of the fourth embodiment, except that the position of the bottom is estimated using the position of the top. The way of finding the position of the top has been explained in the flowchart of the fourth embodiment and therefore a flowchart of the fifth embodiment will be omitted.

In the third embodiment, to find the position of the top of the distribution, a threshold value for searching for the top from the maximum value (max) of the distribution has been found. However, this is not restrictive. For example, as in the fourth and fifth embodiments, simplified methods may be used as follows: when a value of the histogram is equal to or larger than 300, it is regarded as the top; the central value of a Vth level range where the values of the histogram are equal to or larger than 300 is determined to be the position of the top; or the position of the top is estimated in a position where the range of top region is divided at a predetermined rate.

In the fifth embodiment, when the top of the distribution has been detected in searching for the bottom of the distribution and when the bottom of the distribution to be detected is not included in the search range, the position of the bottom is estimated by combining the upper parts of the shapes of the top of the distribution. Therefore, when the shift amount of Vth is larger than estimated, the position of the bottom of the distribution can be detected without performing distribution reading again.

### Sixth Embodiment

FIGS. 55A, 55B to FIGS. 62A, 62B show an example of estimating Vth at the bottom of a distribution by applying a linear function or a drawing method equivalent to a linear function to a histogram of weighted average values according to a sixth embodiment.

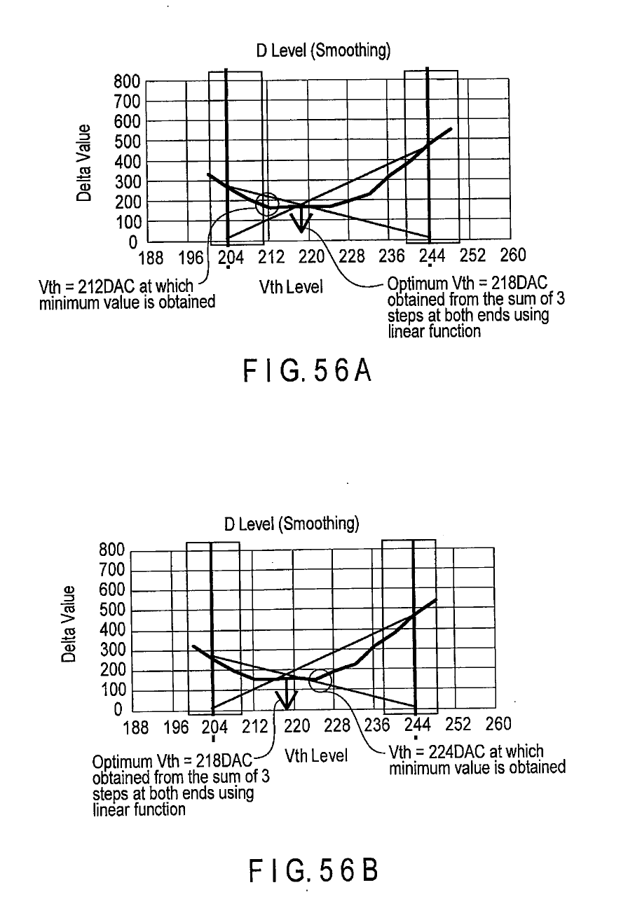

FIGS. 55A, 56A, . . . , 62A correspond to a histogram created from data read from an actual NAND flash memory corresponding to FIG. 27. FIGS. 55B, 56B, . . . , 62B correspond to a histogram created from data obtained by intentionally adding an error of 15 in distribution reading to Vth=226DAC in data read from an actual NAND flash memory corresponding to FIG. 28. Both of them are shown to inform that the effect of an error in distribution reading on the result obtained in the sixth embodiment is small.

FIGS. 55A and 55B show cases where it has been known that a peak of the top of the distribution is not included in the search range in estimating the Vth at one bottom of the distribution. In this case, two straight lines are drawn from both ends of a histogram of weighted average values in the search range (e.g., 200DAC to 248DAC) toward a point where each difference data item becomes “0” so as to cross each other. The intersection of the two straight lines is estimated to be the bottom of the distribution.

According to this method, the bottom can be estimated to be at almost the same Vth as in the first embodiment.

FIGS. 56A and 56B show cases where it has been known that a peak of the top of the distribution is not included in the search range in estimating Vth at one bottom of the distribution. In this case, three steps at both ends of a weighted average histogram are averaged in the search range. Then, two straight lines are drawn from the Vth at the center of the three steps at either end of the histogram toward a point where each difference data item becomes “0” so as to cross each other. The intersection of the two straight lines is estimated to be the bottom of the distribution.

According to this method, the bottom can be estimated to be at almost the same Vth as in the first embodiment.

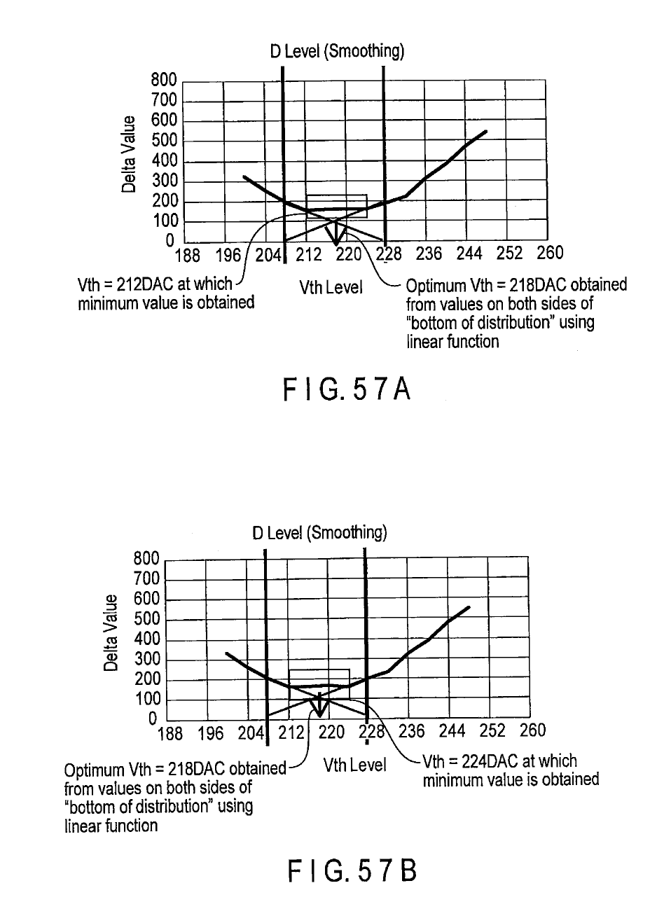

In FIGS. 57A and 57B, two straight lines are drawn from the positions of both ends of the bottom of the distribution in a histogram detected in the first embodiment toward a point where each difference data item becomes “0” so as to cross each other. The intersection of the two straight lines is estimated to be the bottom of the distribution.

According to this method, too, the bottom can be estimated to be at almost the same Vth as in the first embodiment.

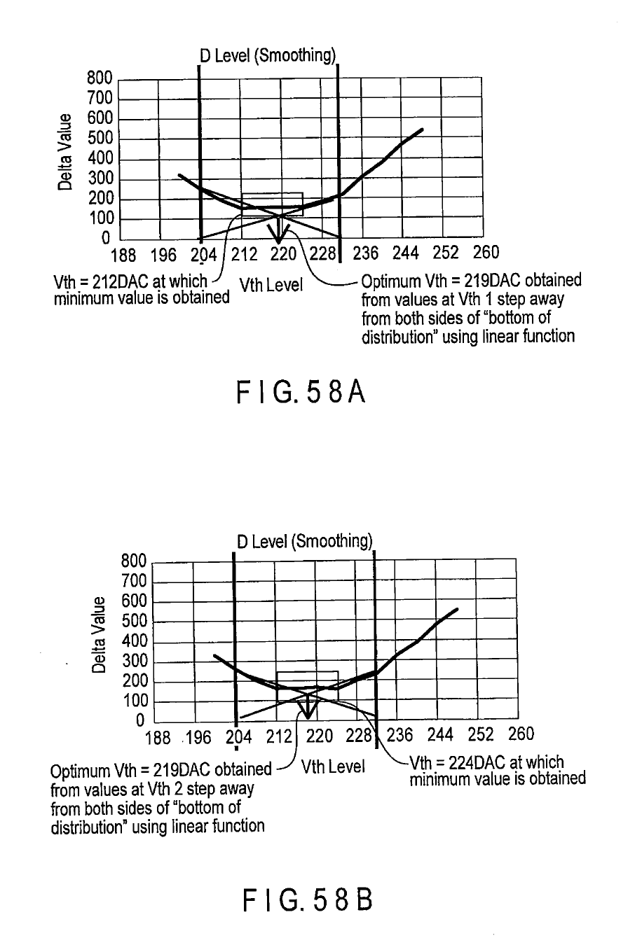

In FIGS. 58A and 58B, two straight lines are drawn from the positions (232DAC) one step (4DAC) outside either end of the bottom of the distribution in a histogram detected in the first embodiment toward a point where each difference data item becomes “0” so as to cross each other. The intersection of the two straight lines is estimated to be the bottom of the distribution.

According to this method, too, the bottom can be estimated to be at almost the same Vth as in the first embodiment.

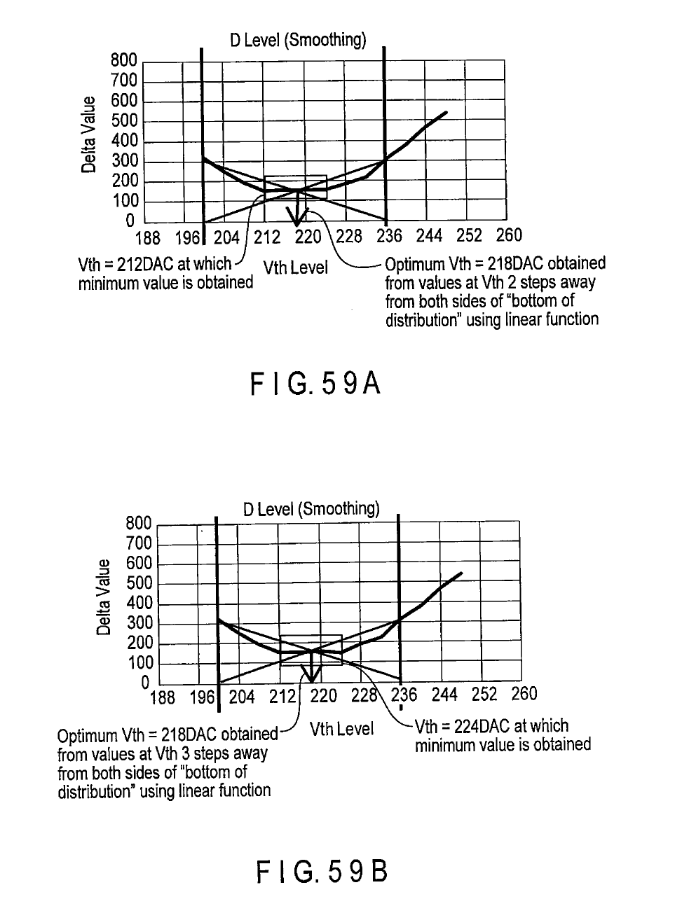

In FIGS. 59A and 59B, two straight lines are drawn from the positions (236DAC) two steps outside either end of the bottom of the distribution in a histogram detected in the first embodiment toward a point where each difference data item becomes “0” so as to cross each other. The intersection of the two straight lines is estimated to be the bottom of the distribution.

According to this method, too, the bottom can be estimated to be at almost the same Vth as in the first embodiment.

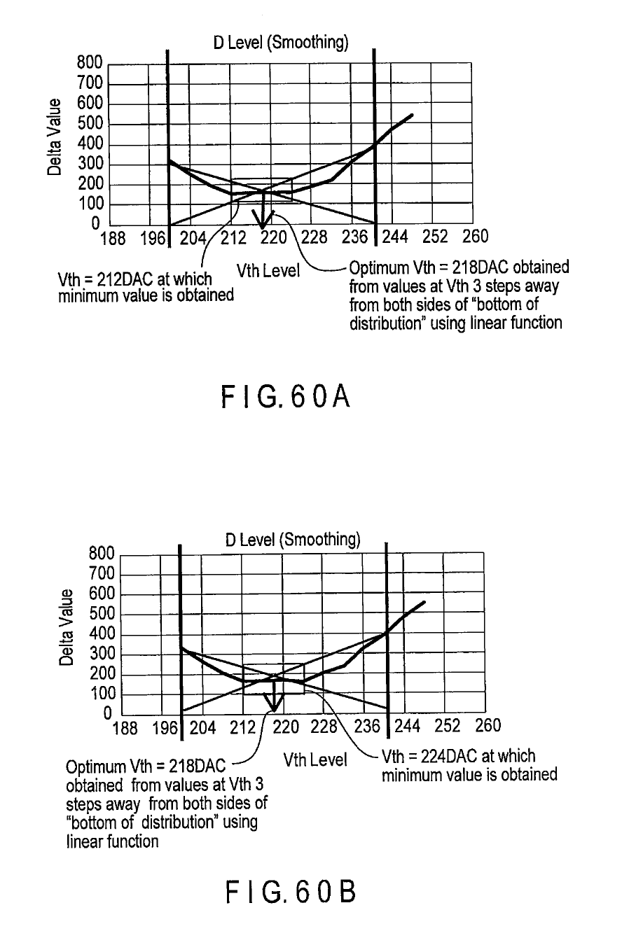

In FIGS. 60A and 60B, two straight lines are drawn from the positions (240DAC) three steps outside either end of the bottom of the distribution in a histogram detected in the first embodiment toward a point where each difference data item becomes “0” so as to cross each other. The intersection of the two straight lines is estimated to be the bottom of the distribution.

According to this method, too, the bottom can be estimated to be at almost the same Vth as in the first embodiment.

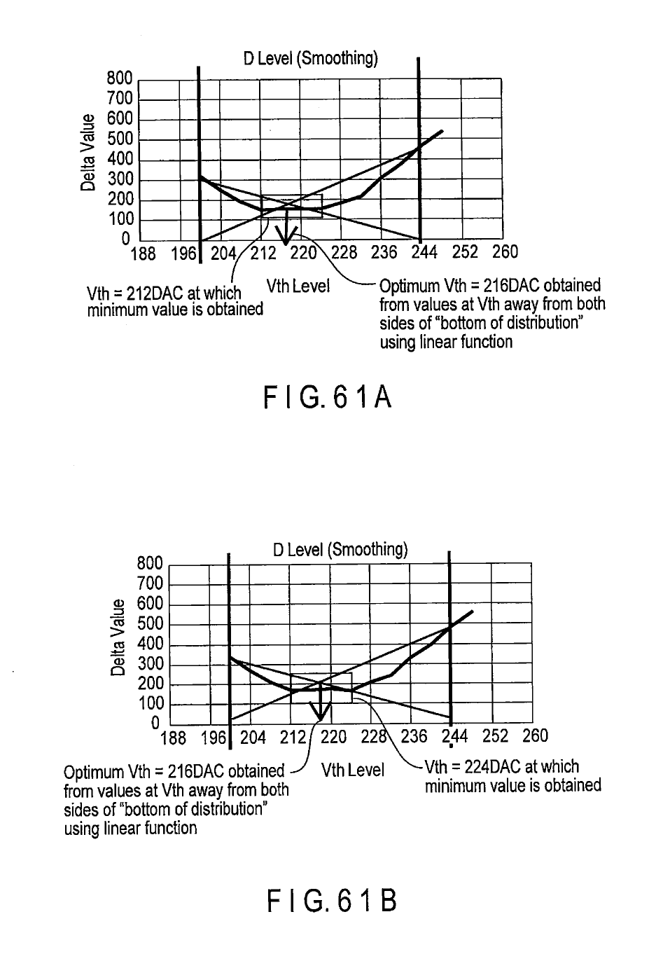

In FIGS. 61A and 61B, an attempt was made to draw two straight lines from the positions one step (4DAC) outside the search range of FIGS. 60A and 60B, that is, from the positions four steps outside either end of the bottom of the distribution in a histogram detected in the first embodiment. However, since the negative side of the bottom of the distribution has reached the lower limit of the search of Vth tracking, two straight lines are drawn from the upper-limit positions (244DAC) one step (4DAC) outside the histogram in FIGS. 60A and 60B toward a point where each difference data item becomes “0” so as to cross each other. The intersection of the two straight lines is estimated to be the bottom of the distribution.

According to this method, too, the bottom can be estimated to be at almost the same Vth as in the first embodiment.

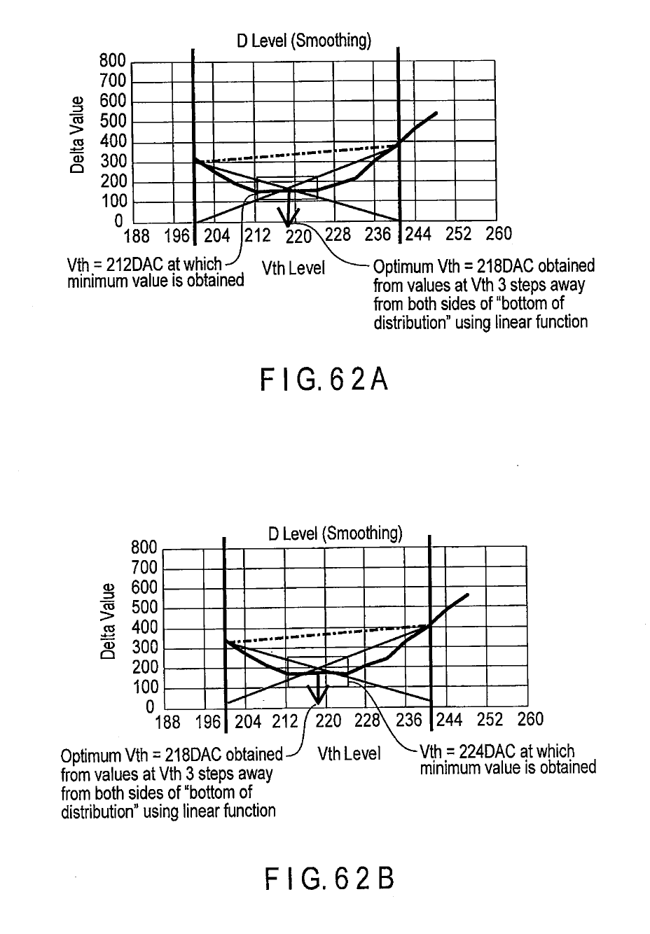

In FIGS. 62A and 62B, an attempt was made to draw two straight lines from the positions two steps (8DAC) outside the search range of FIGS. 60A and 60B, that is, from the positions five steps outside either end of the bottom of the distribution in a histogram detected in the first embodiment. However, since the negative side of the bottom of the distribution has reached the lower limit of the search of Vth tracking, two straight lines are drawn from the upper-limit positions (248DAC) two steps (8DAC) outside the histogram in FIGS. 60A and 60B toward a point where each difference data item becomes “0” so as to cross each other. The intersection of the two straight lines is estimated to be the bottom of the distribution.

According to this method, too, the bottom can be estimated to be at almost the same Vth as in the first embodiment.

Although not shown, in FIG. 57A, several steps from both ends of the bottom of the distribution are averaged and two straight lines are drawn from the central ones of the averaged Vths so as to cross each other as shown in FIG. 56A, producing the same result.

In addition, although not shown, the methods of FIGS. 55A, 55B to FIGS. 62A, 62B are applied to a histogram based on difference data before weighted average, not to a weighted average histogram, which produces the same result.

In FIGS. 55A, 55B to FIGS. 62A, 62B, read data from an actual NAND flash memory or data equivalent to the read data has been used.

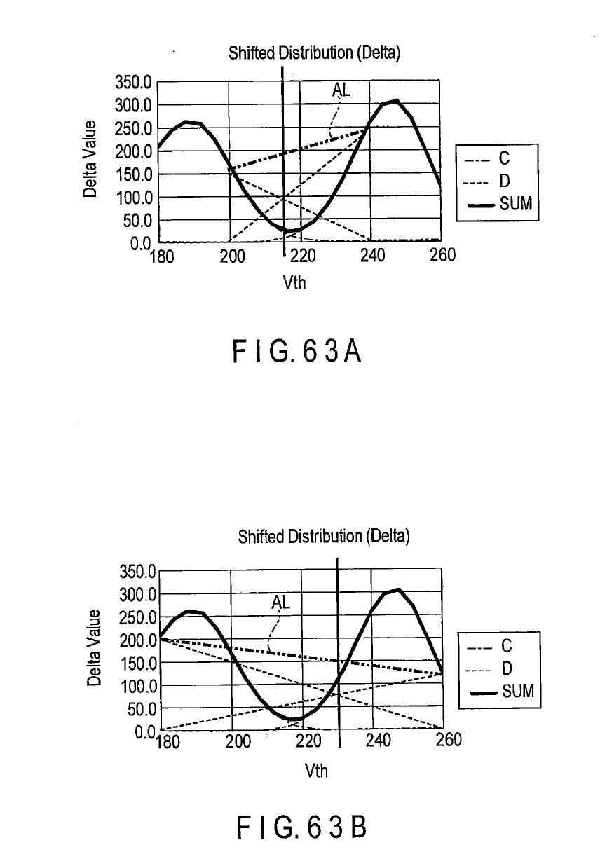

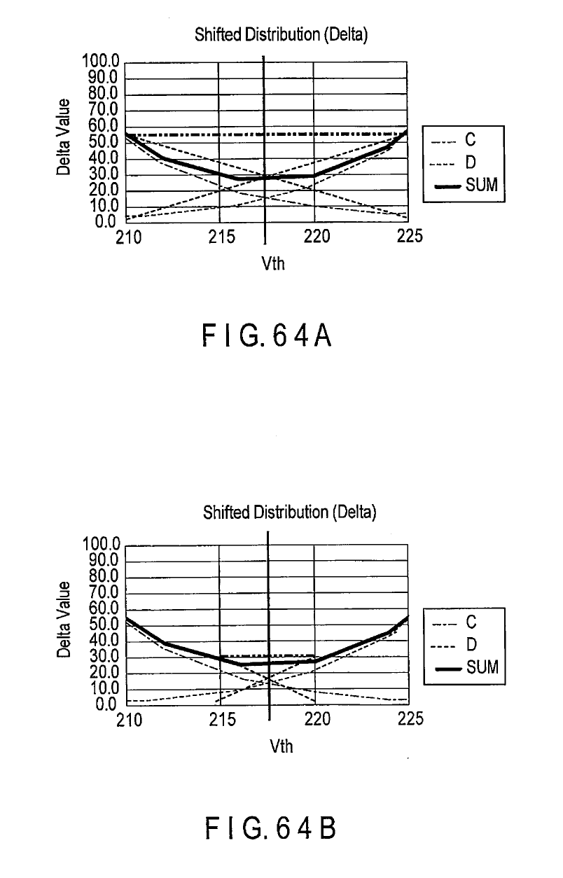

In contrast, FIGS. 63A, 63B and FIGS. 64A, 64B show cases where the same method has been applied to a distribution obtained by making calculations on the assumption of a normal distribution.

In FIG. 63A, with a point where Vth is 200DAC and a point where Vth is 240DAC, two straight lines are drawn from the points where a histogram of SUM of a distribution of C level data and D level data crosses perpendiculars passing 200DAC and 240DAC toward the point where Vth is 200DAC and the point where Vth is 240DAC so as to cross each other. The intersection of the two straight lines is estimated to be the bottom of the distribution.

With the bottom of the distribution estimated in this way, the minimum value of the SUM histogram and Vth near the intersection of a C level data distribution and a D level data distribution are estimated. This corresponds to a first-order approximation whereby the C level distribution and D level distribution are approximated by straight lines drawn to estimate the bottom of the distribution and SUM is approximated by a straight line connecting the position where Vth is 200DAC and the point where Vth is 240DAC on the SUM histogram (auxiliary line AL in FIG. 63), thereby estimating the intersection of a C level distribution curve and a D level distribution curve.

Therefore, when the first-order approximation is close to an actual distribution, a good approximation is achieved near the intersection of the C level distribution curve and D level distribution curve. Therefore, using this method near the bottom of the distribution obtained by the method of the first embodiment enables the intersection of distribution curves at two levels to be obtained with a higher accuracy than by the method of the first embodiment.

Methods shown in FIGS. 57A, 57B to FIGS. 59A, 59B are examples close to a first-order approximation distribution.

Methods shown in FIGS. 60A, 60B to FIGS. 62A, 62B correspond to cases where the center value found by method 1 deviates from the actual center value. The methods in FIGS. 60A, 60B to FIGS. 62A, 62B show that, even if the estimation proves wrong due to the fluctuation of distribution reading, the bottom of the distribution can be corrected to a position near the intersection of the two levels by performing the processes as shown in FIGS. 60A, 60B to FIGS. 62A, 62B.

This method is effective in a range where the distribution can be approximated by a first-order approximation. However, when the distribution cannot be regarded as a first-order approximation, for example, when the top of the distribution has been exceeded, an error becomes greater.

FIG. 63B shows an example of applying this method to a case where the top of the distribution has been exceeded. In FIG. 63B, since the top of the distribution has been exceeded, a straight line has a different slope from a distribution near the intersection of a C level distribution and a D level distribution. From this, it is seen that an error becomes much greater than the estimated value shown in FIG. 63A.

FIGS. 64A and 64B show examples of applying this method near the bottom of the distribution. In FIGS. 64A and 64B, the intersection of an actual C level distribution and an actual D level distribution is approximated very well.

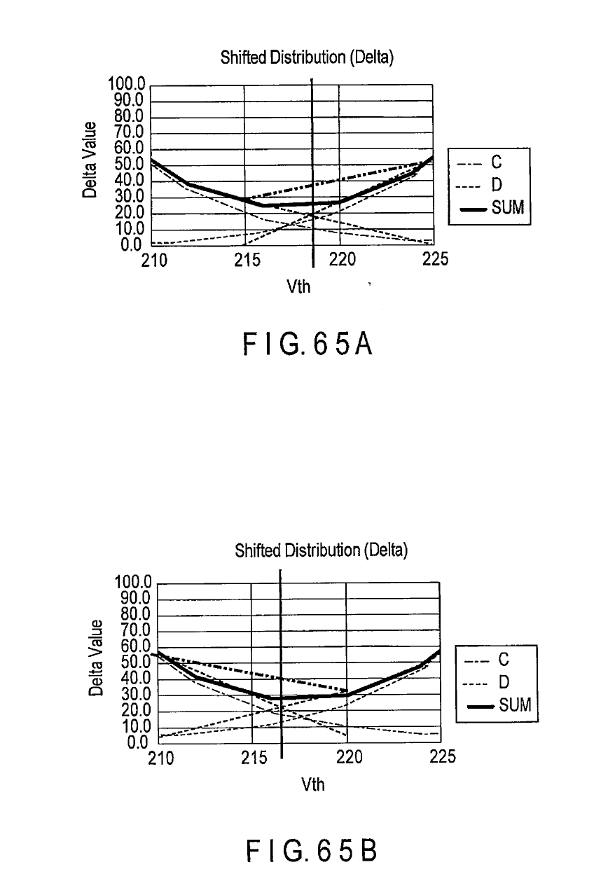

FIGS. 65A and 65B show cases where the Vth combinations in FIGS. 64A and 64B are interchanged and where the intersection of distributions cannot be set in the center on account of steps of distribution reading. Although errors in FIGS. 65A, 65B are greater than in FIGS. 64A, 64B, the position of the bottom of Vth is corrected to the central value of Vth of the two straight lines crossing each other, that is, a position closer to the intersection of the C level distribution and the D level distribution than 220DAC in FIG. 65A and 215DAC in FIG. 65B.

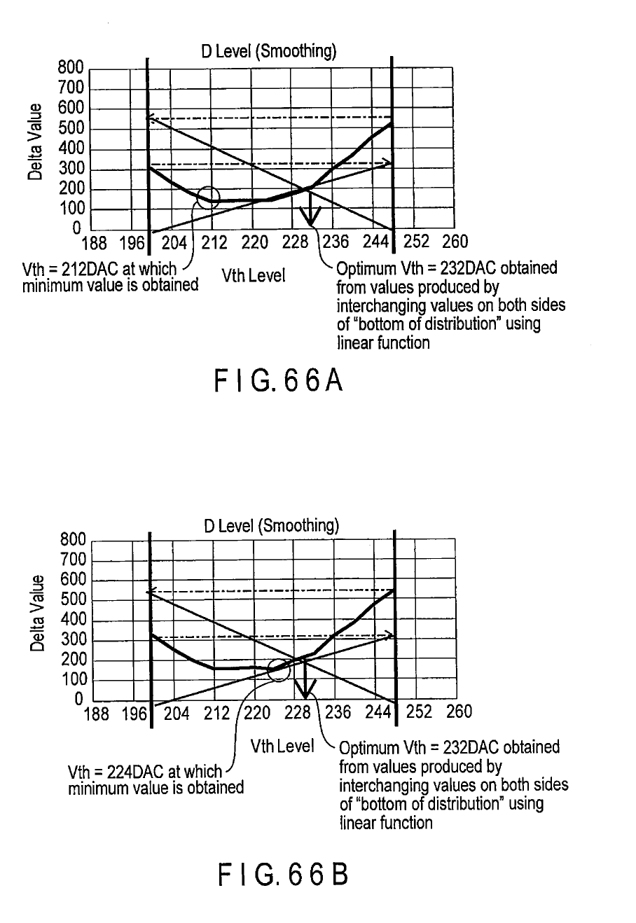

FIGS. 66A and 66B show examples of interchanging the values of a histogram and crossing two straight lines. When a data distribution in a NAND flash memory is close to a normal distribution, the methods in FIGS. 55A, 55B to FIGS. 62A, 62B give better approximations. However, when a data distribution in a NAND flash memory has a different pattern, the methods shown in FIGS. 66A, 66B may be more suitable for the pattern.

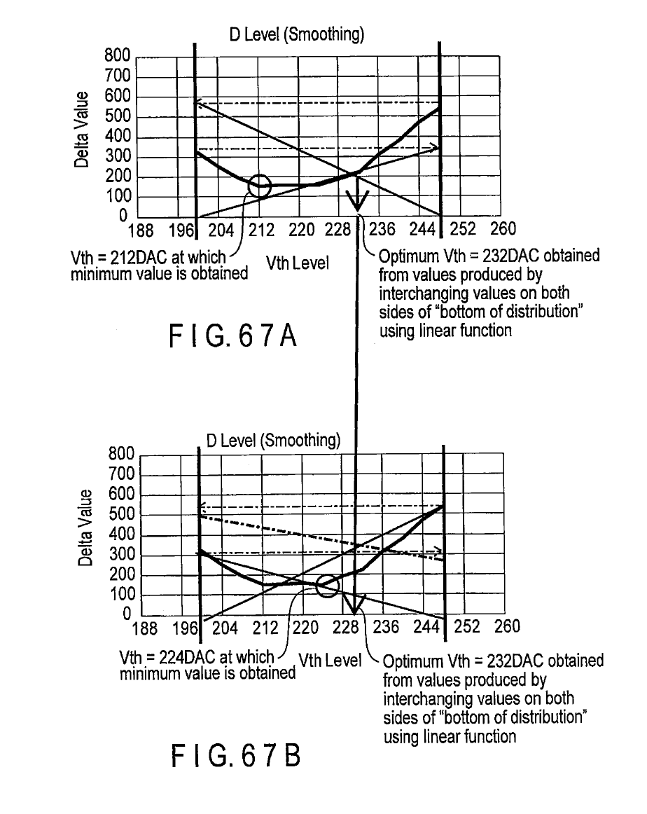

Approximation in FIGS. 66A, 66B will be explained with reference to FIGS. 67A, 67B. FIG. 67A shows an example of estimation in FIG. 66A. An arrow shown in FIG. 67B shows a distribution estimated by this approximation method. Two triangles enclosed by two straight lines crossing each other and a vertical line drawn from the intersecting point of an arrow written near 230DAC are error distributions. It is seen from the approximation that the base of a triangle formed by a sharply-sloping straight line, a vertical line, and the x-axis is longer than the base of a triangle formed by a gently-sloping straight line, a vertical line, and the x-axis and therefore the rate of data items moved from the D level to the C level becomes very large, which prevents a good approximation from being obtained.

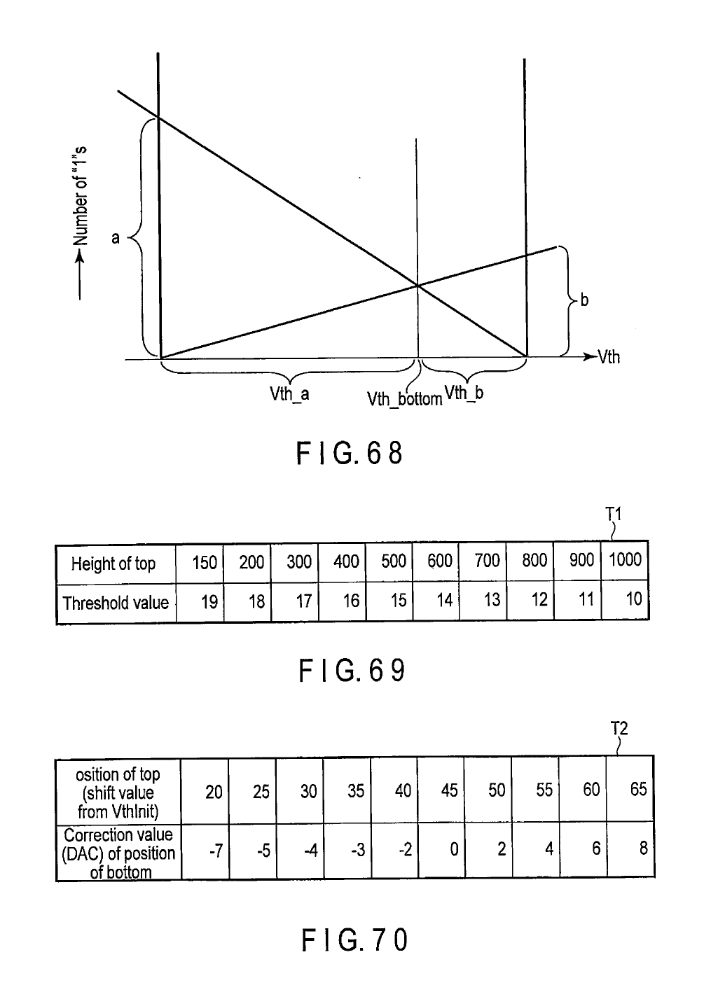

FIG. 68 shows a method of calculating an approximate equation that represents the values of the intersections on the horizontal axis shown in FIGS. 55A to 65B.

A horizontal axis range W is represented by equation (19) using a horizontal axis range (Vth) through which two straight lines are drawn so as to cross each other and the values (the number of “1”s) on the vertical axis of the two straight lines crossing each other:

W=W*(a/(a+b))+W*(b/(a+b)) (19)

where “a” is the value (the number of “1”s) on a vertical axis on the left side of the two straight lines crossing each other, and

“b” is the value (the number of “1”s) on a vertical axis on the right side of the two straight lines crossing each other.

Therefore, if the value on the x-axis on the left side of the two straight lines crossing each other is (Vth_a) and

the value on the x-axis on the right side of the two straight lines crossing each other is (Vth_b),

then the horizontal axis range W is represented by equation (20):

W=Vth_{—}b−Vth_{—}a (20)

Therefore, intersection Vth_bottom is represented by equation (21):

$$\begin{matrix}Vth\_bottom = Vth\_a + W * ( a / ( a + b ) ) \\ = Vth\_a + ( Vth\_b - Vth\_a ) * ( a / ( a + b ) ) \\ = Vth\_a * b / ( a + b ) + Vth\_b * a / ( a + b )\end{matrix} \qquad ( 21 )$$

Since the intersections in FIGS. 66A to 67B are obtained by interchanging “a” and “b” in equation (19), intersection Vth_bottom′ is represented by equation (22):

$$\begin{matrix}{Vth\_bottom}^{′} = Vth\_a + W * ( b / a + b ) \\ = Vth\_a * a / ( a + b ) + Vth\_b * b / ( a + b )\end{matrix} \qquad ( 22 )$$

Although equation (21) is effective in estimating the position of the intersection, equation (22) may be effective, depending on conditions.

Moreover, the distribution is not limited to the normal distribution, and can assume another provability distribution, such as binomial distribution, χ(Chi)-square distribution, F-distribution, and t-distribution, for example.

### Seventh Embodiment

FIG. 69 is a table according to a seventh embodiment.

In the first, second, and fourth embodiments, a threshold value for finding the bottom of a distribution has been calculated from the minimum value and margin of a histogram. However, this is not restrictive. A threshold value may be set using table T1 as shown in FIG. 69 which has been prepared on the basis of the maximum value of a histogram.

In table T1 of FIG. 69, threshold values are set with respect to the height of the top. That is, when a normal distribution is assumed, for example, the position of the bottom adjacent to a high distribution becomes lower as the adjacent top is higher in a histogram obtained by summing the values of the individual levels as shown in FIGS. 6 and 7. Therefore, as shown in FIG. 69, as the height of a distribution becomes greater, a smaller threshold value is set.

Table T1 shown in FIG. 69 is stored in, for example, the NAND flash memory 20. The contents of table T1 are read by the controller 11a when distribution reading is performed and are stored in, for example, the RAM 15. In the second search operation, the controller 11a selects a threshold value, referring to table T1 on the basis of the maximum value of the top detected in the first search operation, and performs the second search operation.

The threshold values in FIG. 69 are not limited to the threshold values of the bottom of the distribution and may be used as a margin added to, for example, the minimum value.

With the seventh embodiment, use of a table that shows the relationship between the heights of distributions and threshold values makes it unnecessary to calculate threshold values, enabling the processing speed to be made faster.

### Eighth Embodiment

FIG. 70 is a table according to an eighth embodiment.

The third, fourth, and fifth embodiments have made calculations to estimate the position of the bottom of a distribution using the top of the distribution.

In contrast, in the eighth embodiment, there is provided table T2 in which correction values of the position of the bottom have been set previously so as to correspond to the position of the top (shift values from the initial value of Vth) as shown in FIG. 70. As in the seventh embodiment, when distribution reading is performed, table T2 is read by the controller 11a and stored in, for example, the RAM 15. The controller 11a finds correction values of the position of the bottom of a distribution, referring to table T2 on the basis of the initial value of Vth and estimates the position of the bottom of the distribution.

With the eighth embodiment, use of a table that shows the relationship between the positions of the top and correction values of the position of the bottom makes it unnecessary to do calculations to estimate the position of the bottom of the distribution, enabling the processing speed to be made faster.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory which includes a plurality of memory cells, each of which stores data when one of an n number of threshold voltages (n being a natural number not less than two) is set; and
a controller which reads data from the memory and which
reads data from the memory cells at each of the threshold voltages in a read operation that checks a distribution of threshold voltages of the memory cells,
calculates difference data on data read at each of the threshold voltages,
calculates a minimum value of the distribution of the threshold voltages from the difference data,
calculates a range of threshold voltages lower than the minimum value based on the minimum value, and
sets a central voltage in the calculated range of threshold voltages as a read voltage.

2. The semiconductor memory device of claim 1, wherein the controller calculates a weighted average of the difference data and calculates a minimum value of a distribution of the threshold voltages from the weighted average data.

3. The semiconductor memory device of claim 2, wherein the controller adds a margin to the minimum value to set a threshold value when calculating a range of threshold voltages lower than the minimum value based on the minimum value and calculates a range of threshold voltages lower than the threshold value.

4. The semiconductor memory device of claim 1, wherein the controller reads data “1” from the memory cells at each of the threshold voltages in the read operation and counts the number of the data “1”s at each of the threshold voltages.

5. The semiconductor memory device of claim 4, wherein the controller calculates difference data on the number of the data “1”s counted at each of the threshold voltages.

6. A semiconductor memory device comprising:
a memory which includes a plurality of memory cells each of which stores data when one of an n number of threshold voltages (n being a natural number not less than two) is set; and
a controller which reads data from the memory and which
reads data from the memory cells at each of the threshold voltages in a read operation that checks a distribution of threshold voltages of the memory cells,
calculates difference data on data read at each of the threshold voltages,
calculates a maximum value of the distribution of the threshold voltages from the difference data,
calculates a range of threshold voltages higher than the maximum value based on the minimum value, and
sets a central voltage in the calculated range of threshold voltages as a read voltage.

7. The semiconductor memory device of claim 6, wherein the controller calculates a weighted average of the difference data and calculates a maximum value of a distribution of the threshold voltages from the weighted average data.

8. The semiconductor memory device of claim 6, wherein the controller reads data “1” from the memory cells at each of the threshold voltages in the read operation and counts the number of the data “1”s at each of the threshold voltages.

9. The semiconductor memory device of claim 8, wherein the controller calculates difference data on the number of the data “1”s counted at each of the threshold voltages.

10. A semiconductor memory device comprising:
a memory which includes a plurality of memory cells each of which stores data when one of an n number of threshold voltages (n being a natural number not less than two) is set; and
a controller which reads data from the memory and which
reads data from the memory cells at each of the threshold voltages in a read operation that checks a distribution of threshold voltages of the memory cells,
calculates difference data on data read at each of the threshold voltages,
performs a first search operation of detecting a threshold voltage corresponding to a maximum value higher than a first threshold value based on the difference data and further detecting threshold voltages which are lower than a second threshold value and correspond to a first and a second minimum value lying on both sides of the maximum value,
sets a first and a second bottom region including the first and second minimum values based on the threshold values corresponding to the first and second minimum values detected in the first search operation and performing a second search operation, and
detects threshold voltages corresponding to minimum values of a first and a second threshold voltage from the central positions of the first and second bottom regions.

11. The semiconductor memory device of claim 10, wherein the first and second bottom regions are set in such a manner that a margin is added to the first and second minimum values, respectively.

12. The semiconductor memory device of claim 11, wherein the threshold voltage corresponding to the first minimum value is obtained by subtracting the difference between a threshold voltage corresponding to the top and a threshold voltage of a top adjacent to a position with a lower threshold voltage than that of the top from the threshold voltage corresponding to the top, and
the threshold voltage corresponding to the second minimum value is obtained by adding the difference between the threshold voltage corresponding to the top and a threshold voltage of a top adjacent to a position with a higher threshold voltage than that of the top to the threshold voltage corresponding to the top.

13. The semiconductor memory device of claim 10, wherein the controller, when searching for a threshold voltage of a bottom of a distribution, draws two straight lines from both ends of difference data in a search range toward a point where difference data becomes “0” so that the lines may cross each other and estimates the intersection of the two straight lines to be a bottom of the distribution.

14. The semiconductor memory device of claim 10, wherein the first and second bottom regions are set in such a manner that a margin is added to the first and second minimum values obtained in the first search operation, respectively.

15. The semiconductor memory device of claim 10, further comprising a first table in which threshold values are set so as to correspond to values of the top of the distribution.

16. The semiconductor memory device of claim 15, wherein the controller selects threshold values in the first table based on a maximum value obtained in the first search operation and sets the first and second bottom regions.

17. The semiconductor memory device of claim 10, further comprising a second table in which correction values of the position of the bottom are set so as to correspond to the position of the top.

18. The semiconductor memory device of claim 17, wherein the controller selects a correction value of the position of the bottom in the second table based on the position of the top and estimates the position of the bottom.

19. The semiconductor memory device of claim 10, wherein the controller reads data “1” from the memory cells at each of the threshold voltages in the read operation and counts the number of the data “1”s at each of the threshold voltages.

20. The semiconductor memory device of claim 19, wherein the controller calculates difference data on the number of the data “1”s counted at each of the threshold voltages.
